(19) United States
(12) Patent Application Publication
(10) Pub. No.: US 2026/0035396 A1
(43) Pub. Date: Feb. 5, 2026

(54) LIQUID MOLYBDENUM BIS(ARENE) COMPOSITIONS FOR DEPOSITION OF MOLYBDENUM-CONTAINING FILMS

(71) Applicant: Versum Materials US, LLC, Tempe, AZ (US)

(72) Inventors: Sergei Ivanov, Schnecksville, PA (US); Guocang Wang, Allentown, PA (US)

(21) Appl. No.: 19/101,081

(22) PCT Filed: Jul. 18, 2023
(86) PCT No.: PCT/US2023/070396

§ 371 Date: Feb. 4, 2025

Related U.S. Application Data
(60) Provisional application No. 63/370,531, filed on Aug. 5, 2022.

(51) Int. Cl. C07F 11/00; C23C 16/455

(52) U.S. Cl. CPC C07F 11/00; C23C 16/45553

(57) ABSTRACT

The disclosed and claimed subject matter relates to mixtures of Mo(arene)2 compounds and uses thereof for deposition of Mo-containing films. The arene ligands are selected to provide mixtures of Mo(arene)2 compounds that are liquid at temperatures of about 20° C. and about 35° C. where there is little or no differences in boiling points between different components of the mixture.

### BACKGROUND

### Field

The disclosed and claimed subject matter relates to compositions including mixtures of Mo(arene)₂ complexes and uses thereof for deposition of Mo-containing films. The arene ligands are selected to provide mixtures of Mo(arene)₂ compositions that are liquid at temperatures of about 20° C. and about 35° C. where there is little or no differences in boiling points between different components of the mixture. In some embodiments all of the arene ligands have substantially the same or the same molecular weight. In other embodiments all of the arene ligands have the same number of carbons.

### Related Art

Transition metal-containing films are used in semiconductor and electronics applications. Chemical Vapor Deposition (CVD) and Atomic Layer Deposition (ALD) have been applied as the main deposition techniques for producing thin films for semiconductor devices. These methods enable the achievement of conformal films (metal, metal oxide, metal nitride, metal silicide, and the like) through chemical reactions of metal-containing compounds (precursors). The chemical reactions occur on surfaces which may include metals, metal oxides, metal nitrides, metal silicides, and other surfaces. In CVD and ALD, the precursor molecule plays a critical role in achieving high quality films with high conformality and low impurities. The temperature of the substrate in CVD and ALD processes is an important consideration in selecting a precursor molecule. Higher substrate temperatures, in the range of 150 to 500 degrees Celsius (° C.), promote a higher film growth rate. The preferred precursor molecules must be stable in this temperature range. The preferred precursor is capable of being delivered to the reaction vessel in a liquid phase. Liquid phase delivery of precursors generally provides a more uniform delivery of the precursor to the reaction vessel than solid phase precursors.

CVD and ALD processes are increasingly used as they have the advantages of enhanced compositional control, high film uniformity, and effective control of doping. Moreover, CVD and ALD processes provide excellent conformal step coverage on highly non-planar geometries associated with modern microelectronic devices.

CVD is a chemical process whereby precursors are used to form a thin film on a substrate surface. In a typical CVD process, the precursors are passed over the surface of a substrate (e.g., a wafer) in a low pressure or ambient pressure reaction chamber. The precursors react and/or decompose on the substrate surface creating a thin film of deposited material. Plasma can be used to assist in reaction of a precursor or for improvement of material properties. Volatile by-products are removed by gas flow through the reaction chamber. The deposited film thickness can be difficult to control because it depends on coordination of many parameters such as temperature, pressure, gas flow volumes and uniformity, chemical depletion effects, and time.

ALD is a chemical method for the deposition of thin films. It is a self-limiting, sequential, unique film growth technique based on surface reactions that can provide precise thickness control and deposit conformal thin films of materials provided by precursors onto surfaces substrates of varying compositions. In ALD, the precursors are separated during the reaction. The first precursor is passed over the substrate surface producing a monolayer on the substrate surface. Any excess unreacted precursor is pumped out of the reaction chamber. A second precursor or co-reactant is then passed over the substrate surface and reacts with the first precursor, forming a second monolayer of film over the first-formed monolayer of film on the substrate surface. Plasma may be used to assist with reaction of a precursor or co-reactant or for improvement in materials quality. This cycle is repeated to create a film of desired thickness.

Thin films, and in particular thin metal-containing films, have a variety of important applications, such as in nanotechnology and the fabrication of semiconductor devices. Examples of such applications include capacitor electrodes, gate electrodes, adhesive diffusion barriers and integrated circuits.

Molybdenum-containing thin films have attracted attention due to their lower resistivity and thermal stability compared with other metals like tungsten and cobalt. As a result, molybdenum (Mo) has become an increasingly preferred material in the electronics industry for forming Mo-containing thin films using CVD or ALD techniques in next generation devices. There is ongoing need for halogen-free molybdenum precursors which are liquid at room or low temperature, have relativity high vapor pressure, high thermal stability, and reactivity. Most of known molybdenum precursors contain molybdenum in high oxidation state, 4-6, which typically results in high resistivity molybdenum-containing films. Low oxidation state molybdenum complexes, 0-4, are desired for deposition of low resistivity molybdenum-containing films.

Molybdenum bis(arene) precursors are a series of organometallic compounds of the formula Mo(arene)₂ where the arene is the same or different unsubstituted or substituted benzene like benzene, toluene, mesitylene, ethylbenzene, diethylbenzene and xylene. Such precursors usually have relatively high vapor pressures that make them good candidates for CVD or ALD to produce Mo thin films with low resistivity and low amounts of carbon and nitrogen contaminants. Commercially available mixture including Mo(EtBz)₂ has been used for the deposition of molybdenum-containing films like MoO, MOC seed layer and Mo metallic films.

For example, U.S. Patent Application Publication No. 2022/0139713 A1 describes methods of depositing elemental molybdenum thin film on a substrate using a liquid precursor including molybdenum bis(ethylbenzene). In the method, molybdenum thin film containing carbon as contaminant is deposited on a substrate by a cyclical deposition process followed by oxidation to remove carbon, and the method includes providing a substrate in a deposition chamber, providing a molybdenum precursor to the chamber in a vapor phase and providing a reactant to the reaction chamber in a vapor phase to form molybdenum film on the substrate. The molybdenum precursor is provided in a mixture and the reactants are halogen (12) or halogenated hydrocarbon (ICH₂CH₂I) with at least two halogen atoms are attached to different carbon atoms of the hydrocarbon.

U.S. Patent Application Publication No. 2021/0047726 A1 describes a method of forming a molybdenum thin film using halide free organometallic molybdenum precursors [Mo(EtBz)₂. CpMo(CO)₂(NO) and MeCpMo(CO)₂(NO)] in zero valent state by oxidation and reduction. The first step is the formation of molybdenum oxide film by CVD or ALD, but the film contains low amounts of carbon as contaminant. Consequently, the molybdenum oxide film requires additional processing (i.e., an oxidation) to remove carbon followed by the reduction to remove oxygen and finally form a highly pure molybdenum thin film. The molybdenum thin film has low resistance and properties like bulk molybdenum.

U.S. Patent Application Publication No. 2020/0115798 describes vapor deposition methods for depositing molybdenum or tungsten metal films or layers onto a substrate, the methods involve organometallic molybdenum or tungsten precursors like Mo(EtBz)₂ or W(EtBz)₂ that include only the metal, carbon and hydrogen. The deposited metal layer contains carbon as a contaminant derived from the precursors. Consequently, additional processing is required to remove the carbon; namely, an oxidizer is introduced to react with the carbon contaminant and remove the carbon contaminant from the deposited metal layer to give high quality metal films or layers after flowing hydrogen gas into the deposition chamber to expose the deposited metal to hydrogen.

U.S. Patent Application Publication No. 2019/226086 describes chemical vapor deposition method for depositing molybdenum films onto a titanium nitride surface (3D NAND device with vertical walls) using bis(alkyl-arene) molybdenum composition including Mo(EtBz)₂ as precursors to form MoC seed layer (Mo:C=40:60 to 99:1, thickness: 6-100 Å) or Mo-containing metallic film below 300° C. with the pressure of 10-50 torr.

While deposition of molybdenum-containing films was demonstrated using liquid Mo(Arene)₂ composition containing Mo(EtBz)₂, this commercially available composition contains a mixture of molybdenum arene complexes with different ligands; in particular the mixture includes <60 mol % of ethylbenzene ligands, >10 mol % of benzene ligands, >30 mol % of diethylbenezene ligands and >1 mol % of triethylbenzene. Without being bound by theory it is believed that this composition contains various molybdenum arene complexes, such Mo(Bz)₂, Mo(EtBz)(Bz), Mo(EtBz)₂, Mo(EtBz)(Et₂Bz), Mo(Et₂Bz)₂, Mo(Et₃Bz)₂, etc. These complexes have sufficiently different molecular weight, sufficiently different thermal stability and vapor pressure that leads to inconsistent chemical delivery to the tool and not-reproducible deposition of molybdenum-containing films. It is highly desired to obtain liquid composition wherein arene ligands comprise higher concentration of ethylbenzene to reduce the difference in boiling point of different mixture components

U.S. Patent Application Publication No. US2022/0372053 A1 described a method for forming a metal-containing film on a substrate includes the steps of: exposing the substrate to a vapor of a film forming composition that contains a metal-containing precursor; and depositing at least part of the metal-containing precursor onto the substrate to form the metal-containing film on the substrate through a vapor deposition process wherein the metal-containing precursor is purportedly a pure Mo(arene)₂ like Mo(toluene)₂, Mo(m-xylene)₂, Mo(mesitylene)₂, relative to pure Mo(EtBz)₂ and a commercially available “Mo(EtBz)₂” mixture of metal arene compositions. However, no data is provided establishing the purity of the Mo(arene)₂. In addition, the purportedly pure materials are prepared by previously reported methods (discussed below) without any additional purification steps that are knows to impart impurities. Therefore, although this reference describes that it would be desirable to use “pure” materials in the disclosed methods, it does not describe how to obtain such pure materials. Accordingly, it describes the continuing need for high purity molybdenum arenes complexes substantially free of impurities which impact quality of deposited molybdenum-containing film.

Preparation of compositionally pure Mo(EtBz)₂ complex is not directly possible by the Fischer-Hafner method. The Fischer-Hafner method suffers from isomerization of the alkylbenzenes with alkyl group larger than methyl. Thus, such molybdenum arene complexes contain mixtures of various arenes with different molecular weights. For example, when ethylbenzene is used in the synthesis of Mo(arene)₂ complexes, the arene ligands comprise a mixture of benzene, ethylbenzene, diethylbenzene and tri-ethylbenzene wherein the amount of ethylbenzene is <60 mol %. On the other hand, relatively pure Mo(arene)₂ complexes could be prepared using benzene, methylbenzene (toluene), dimethylbenzene (xylene) and trimethylbenzene (mesitylene). However, all these complexes are solids with melting point above 80° C.: Mo(Benzene)₂ (mp=115° C.), Mo(Toluene)₂ (mp=82° C.), Mo(m-xylene)₂ (mp=104° C.), Mo(Mesitylene)₂ (mp=110° C.).

M. T. Ashby, et al. in Organometallics. 20, 1687-1688 (2001) used arene metathesis with Mo(benzene)₂ complex to produce Mo(RC₆H₅)₂ (R=Et, ⁱPr, ^{t}Bu). However, all of the complexes are solids produced with low yields due to thermal instability of Mo(benzene)₂. In addition, these compositions still have residual Mo(benzene)₂ which has different vapor pressure and low thermal stability. Thus, there is still a need for molybdenum arene compositions substantially free of Mo(benzene)₂.

It is highly desired to obtain mixtures of Mo(arene)₂ compounds which are liquids at room temperature. This is because it is much easier to transport the liquid from the bulk container into the onboard container on semiconductor tool. Typically, compositions with melting point <35° C. are preferred.

It is also desired to obtain liquid mixtures of Mo(Arene)₂ compounds wherein all arene ligands have the same or substantially the same molecular weight. Without being bound by theory it is believed that all components of these mixtures will have similar boiling point, and correspondingly maintain its composition during evaporation from the ampoule on semiconductor tool.

The disclosed and claimed subject matter overcomes the above deficiencies by providing liquid mixtures of Mo(Ar¹)(Ar²) compounds with consistent vapor pressures that are particularly well-suited for use in CVD and ALD applications

### SUMMARY

The disclosed and claimed subject matter relates to mixtures of Mo(Ar¹)(Ar²) compounds prepared via arene metathesis in which the amount of ethylbenzene ligand (“EtBz”) content in the compositions is increased from about 54% (commercial grade) to between about 60 mol % to about 95 mol % along with concomitant decreases in undesirable ligands, i.e., benzene ligand (“Bz”), diethylbenzene ligand (“Et₂Bz”) and triethylbenzene ligand (“Et₃Bz”). Significantly, this compositional change still provides a room-temperature liquid composition having a much more consistent vapor pressure during evaporation.

In one embodiment, for example, the liquid mixtures of Mo(Ar¹)(Ar²) compounds include (i) about 60 mol % to about 95 mol % of EtBz and (ii) reduced amounts of other undesirable ligands. In a further aspect of this embodiment, the liquid mixtures of Mo(Ar¹)(Ar²) compounds include (i) about 60 mol % to about 95 mol % of EtBz and (iia) about 0.25 mol % to about 13 mol % of Bz, (iib) about 6.75 mol % to about 44.5 mol % of Et₂Bz and (iic) about 0.75 mol % to about 7 mol % of Et₃Bz. That these compositions are liquid at room temperature is very unexpected given, for example, that a mixture of Mo(Ar¹)(Ar²) compounds containing above about 97% of EtBz, about 0.48% of Bz and about 2.35% of Et₂Bz is a solid below 37° C. (melting point). Thus, the disclosed and claimed compositions include a significantly increased amounts of desirable ligands (e.g., ethyl benzene ligand) while also unexpectedly being able to be maintained as liquids at room temperature.

In one embodiment the liquid mixtures of Mo(Ar¹)(Ar²) compounds include >60 mol % of EtBz and <about 1 mol % of each of Bz and of Et₃Bz.

In one embodiment the liquid mixtures of Mo(Ar¹)(Ar²) compounds include <about 1 mol % of each of Bz and/or Et₃Bz. In one embodiment the liquid mixtures of Mo(Ar¹)(Ar²) compounds include <about 0.5 mol % of each of Bz and/or Et₃Bz. In one embodiment the liquid mixtures of Mo(Ar¹)(Ar²) compounds include <about 0.1 mol % of each of Bz and/or Et₃Bz. In one embodiment the liquid mixtures of Mo(Ar¹)(Ar²) compounds are free of each of Bz and/or Et₃BZ.

In another embodiment, the disclosed and claimed subject matter includes liquid mixtures of Mo(Ar¹)(Ar²) compounds that include (i) about 60 mol % to about 95% of EtBz, and (ii) at least 5 mol % of dimethylbenzene ligand (“Me₂Bz”). Liquid Mo(Ar¹)(Ar²) compounds including both EtBz and Me₂Bz are more attractive because Mo(EtBz)₂ and Mo(Me₂Bz)₂ and Mo(EtBz)(Me₂Bz) have the same MW and expectedly the same boiling points or vapor pressure.

In one embodiment, the specialized mixtures include Mo(Ar¹)(Ar²) compounds where (i) Ar¹ and Ar² are each a different arene, (ii) Ar¹ and Ar² each have the same number of carbons and (iii) the composition is a liquid within a temperature range of about 20° C. to about 35° C.

In another embodiment, the specialized mixtures include Mo(Ar¹)(Ar²) compounds where (i) Ar¹ and Ar² are each a different arene structure. (ii) Ar¹ and Ar² each have substantially the same or the same molecular weight and (iii) the composition is a liquid within a temperature range of about 20° C. to about 35° C.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates the ¹H NMR of >97% compositionally pure Mo(EtBz)₂ from Example 6;

FIG. 2 illustrates the DSC of >97% compositionally pure Mo(EtBz)₂ from Example 6;

FIG. 3 illustrates the TGA of >97% compositionally pure Mo(EtBz)₂ from Example 6; and

FIG. 4 illustrates the ¹H NMR of the composition from Example 10 containing the mixture of 60% Mo(EtBz)₂, 30% Mo(EtBz)(m-xylene) and 10% Mo(m-xylene)₂

### DETAILED DESCRIPTION

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the disclosed and claimed subject matter (especially in the context of the following claims) are to be construed to cover both the singular and the plural, unless otherwise indicated herein or clearly contradicted by context. The terms “comprising.” “having.” “including.” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the disclosed and claimed subject matter and does not pose a limitation on the scope of the disclosed and claimed subject matter unless otherwise claimed. No language in the specification should be construed as indicating any non-claimed element as essential to the practice of the disclosed and claimed subject matter. The use of the term “comprising” or “including” in the specification and the claims includes the narrower language of “consisting essentially of” and “consisting of.”

Embodiments of the disclosed and claimed subject matter are described herein, including the best mode known to the inventors for carrying out the disclosed and claimed subject matter. Variations of those embodiments may become apparent to those of ordinary skill in the art upon reading the foregoing description. The inventors expect skilled artisans to employ such variations as appropriate, and the inventors intend for the disclosed and claimed subject matter to be practiced otherwise than as specifically described herein. Accordingly, the disclosed and claimed subject matter includes all modifications and equivalents of the subject matter recited in the claims appended hereto as permitted by applicable law. Moreover, any combination of the above-described elements in all possible variations thereof is encompassed by the disclosed and claimed subject matter unless otherwise indicated herein or otherwise clearly contradicted by context.

It will be understood that the term “silicon” as deposited as a material on a microelectronic device will include polysilicon.

For ease of reference. “microelectronic device” or “semiconductor device” corresponds to semiconductor wafers having integrated circuits, memory, and other electronic structures fabricated thereon, and flat panel displays, phase change memory devices, solar panels and other products including solar substrates, photovoltaics, and microelectromechanical systems (MEMS), manufactured for use in microelectronic, integrated circuit, or computer chip applications. Solar substrates include, but are not limited to, silicon, amorphous silicon, polycrystalline silicon, monocrystalline silicon, CdTe, copper indium selenide, copper indium sulfide, and gallium arsenide on gallium. The solar substrates may be doped or undoped. It is to be understood that the term “microelectronic device” or “semiconductor device” is not meant to be limiting in any way and includes any substrate that will eventually become a microelectronic device or microelectronic assembly.

As defined herein, the term “barrier material” corresponds to any material used in the art to seal the metal lines, e.g., copper interconnects, to minimize the diffusion of said metal, e.g., copper, into the dielectric material. Preferred barrier layer materials include tantalum, titanium, ruthenium, hafnium, and other refractory metals and their nitrides and silicides.

As used here, the term “arene” means cyclic hydrocarbons with alternating double and single bonds between carbon atoms (i.e., aromatic rings) and also includes heteroarenes where one or more carbon atoms forming such aromatic rings is replaced by a hetero atom (e.g., oxygen, sulfur, nitrogen, silicon, germarium, phosphorus). Examples of arenes include, for example, benzene, substituted benzene, naphthalene, anthracene and the like. Examples of heteroarenes include, for example, pyridine, furan, indole, benzimidazole, thiophene, benzothiazole and the like.

“Substantially free” is defined herein as less than 0.001 wt. %. The term “free of” means 0.000 wt. %. As used herein, “about” or “approximately” are intended to correspond to within ±5% of the stated value. The terms “substantially free” and “free” can also be related to halide ions (or halides) such as, for example, chlorides, fluorides, bromides and iodides. The level of halide impurities is less than 100 ppm (by weight) measured by ion chromatography (IC), preferably less than 25 ppm measured by IC, and more preferably less than 5 ppm measured by IC, and most preferably 0 ppm measured by IC. In addition, the terms “substantially free” or “free” can also be referred to substantially free of metal ions such as, Li⁺, Na⁺, K⁺, Mg²⁺, Ca²⁺, Al³⁺, Fe²⁺, Fe³⁺, Ni²⁺ and Cr³⁺ as impurities in the molybdenum arene compounds. As used herein, the term “substantially free” as it relates to Li, Na, K, Mg, Ca, Al, Fe, Ni and Cr each of which metal is less than 5 ppm (by weight), preferably less than 3 ppm, and more preferably less than 1 ppm, and most preferably 0.1 ppm as measured by ICP-MS or other analytical method for measuring metals.

In all such compositions, wherein specific components of the composition are discussed in reference to weight percentage (or “weight %”) ranges including a zero lower limit, it will be understood that such components may be present or absent in various specific embodiments of the composition, and that in instances where such components are present, they may be present at concentrations as low as 0.001 weight percent, based on the total weight of the composition in which such components are employed. Note all percentages of the components are weight percentages and are based on the total weight of the composition, that is, 100%. Any reference to “one or more” or “at least one” includes “two or more” and “three or more” and so on.

Where applicable, all weight percents unless otherwise indicated are “neat” meaning that they do not include the aqueous solution in which they are present when added to the composition. For example, “neat” refers to the weight % amount of an undiluted acid or other material (i.e., the inclusion 100 g of 85% phosphoric acid constitutes 85 g of the acid and 15 grams of diluent).

Moreover, when referring to the compositions described herein in terms of weight %, it is understood that in no event shall the weight % of all components, including non-essential components, such as impurities, add to more than 100 weight %. In compositions “consisting essentially of” recited components, such components may add up to 100 weight % of the composition or may add up to less than 100 weight %. Where the components add up to less than 100 weight %, such composition may include some small amounts of a non-essential contaminants or impurities. For example, in one such embodiment, the formulation can contain 2% by weight or less of impurities. In another embodiment, the formulation can contain 1% by weight or less than of impurities. In a further embodiment, the formulation can contain 0.05% by weight or less than of impurities. In other such embodiments, the constituents can form at least 90 wt %, more preferably at least 95 wt %, more preferably at least 99 wt %, more preferably at least 99.5 wt %, most preferably at least 99.9 wt %, and can include other ingredients that do not material affect the performance of the wet etchant. Otherwise, if no significant non-essential impurity component is present, it is understood that the composition of all essential constituent components will essentially add up to 100 weight %.

As those skilled in the art will understand, in the disclosed and claimed subject matter, the Mo-compositions includes arene (Ar) ligands or simply “arenes.” The following abbreviations are used herein for those arene ligands:

| Arene Ligand | Abbreviation |
|---|---|
| Benzene | Bz |
| Dimethylbenzene | Me₂Bz |
| ortho-Dimethylbenzene | o-Me₂Bz |
| meta-Dimethylbenzene | m-Me₂Bz |
| para-Dimethylbenzene | p-Me₂Bz |
| Ethylbenzene | EtBz |
| Diethylbenzene | Et₂Bz |
| ortho-Diethylbenzene | o-Et₂Bz |
| meta-Diethylbenzene | m-Et₂Bz |
| para-Diethylbenzene | p-Et₂Bz |
| Triethylbenzene | Et₃Bz |
| Pyridine | Py |
| Ethylpyridine | EtPy |
| 2,6-Lutidine | Lt |

It is to be understood, that unless a specific isomer of a given arene is specified, that a recitation of an arene that can include more than one isomer can include any single or mixtures of such isomers. Thus, for example, when the abbreviation “Me₂Bz” is used it is to be understood to include any one of o-Me₂Bz, m-Me₂Bz, and p-Me₂Bz, a mixture of two or more of o-Me₂Bz, m-Me₂Bz and p-Me₂Bz or all three of o-Me₂Bz, m-Me₂Bz and p-Me₂Bz.

The headings employed herein are not intended to be limiting; rather, they are included for organizational purposes only.

Disclosed and Claimed Mo(Ar¹)(Ar²) Compositions
I. Improved Mo(Ar¹)(Ar²) Compositions

As disclosed above, in one aspect the disclosed and claimed subject matter is directed to mixtures of Mo(Ar¹)(Ar²) compounds that include (i) about 60 mol % to about 95 mol % ethylbenzene ligand (“EtBz”) and (ii) reduced amounts of other undesirable ligands where the mixtures of compounds are liquid below 35° C. In a further aspect, the liquid Mo(Ar¹)(Ar²) compositions further include (iii) at least 5 mol % of dimethylbenzene ligand (“Me₂Bz”).

In one embodiment, the liquid mixture of Mo(Ar¹)(Ar²) compounds includes (i) about 60 mol % to about 95 mol % of EtBz, (iia) about 0.25 mol % to about 13 mol % of Bz. (iib) about 6.75 mol % to about 44.5 mol % of Et₂Bz and (tic) about 0.75 mol % to about 7 mol % of Et₃Bz. In a further aspect of this embodiment, the liquid mixture of Mo(Ar¹)(Ar²) compounds further includes (iii) at least 5 mol % of Me₂Bz.

In one embodiment, the liquid mixture of Mo(Ar¹)(Ar²) compounds is liquid within a temperature range of about 20° C. to about 35° C. In one embodiment, the liquid mixture of Mo(Ar¹)(Ar²) compounds is liquid at a temperature at or below about 35° C. In one embodiment, the liquid mixture of Mo(Ar¹)(Ar²) compounds is liquid at a temperature at or below about 30° C. In one embodiment, the liquid mixture of Mo(Ar¹)(Ar²) compounds is liquid at a temperature at or below about 25° C. In one embodiment, the liquid mixture of Mo(Ar¹)(Ar²) compounds is liquid at a temperature at or below about 20° C.

In one embodiment, the liquid mixture of Mo(Ar¹)(Ar²) compounds has a viscosity of less than or equal to about 500 cP. In one embodiment, the liquid mixture of Mo(Ar¹)(Ar²) compounds has a viscosity of less than or equal to about 250 cP. In one embodiment, the liquid mixture of Mo(Ar¹)(Ar²) compounds has a viscosity of less than or equal to about 100 cP. In one embodiment, the liquid mixture of Mo(Ar¹)(Ar²) compounds has a viscosity of less than or equal to about 50 cP. In one embodiment, the liquid mixture of Mo(Ar¹)(Ar²) compounds has a viscosity of less than or equal to about 25 cP. In one embodiment, the liquid mixture of Mo(Ar¹)(Ar²) compounds has a viscosity of less than or equal to about 15 cP.

### Ligand Content

### (i) Ethylbenzene (“EtBz”) Ligand

As noted above, in one embodiment the disclosed and claimed liquid mixtures of Mo(Ar¹)(Ar²) compounds include about 60 mol % to about 95 mol % of EtBz. In one embodiment, the disclosed and claimed liquid mixtures of Mo(Ar¹)(Ar²) compounds include 60 mol % to about 90 mol % of EtBz. In one embodiment, the disclosed and claimed liquid mixtures of Mo(Ar¹)(Ar²) compounds include 65 mol % to about 85 mol % of EtBz. In one embodiment, the disclosed and claimed liquid mixtures of Mo(Ar¹)(Ar²) compounds include 70 mol % to about 80 mol % of EtBz. In one embodiment, the disclosed and claimed liquid mixtures of Mo(Ar¹)(Ar²) compounds include 60 mol % to about 65 mol % of EtBz. In one embodiment, the disclosed and claimed liquid mixtures of Mo(Ar¹)(Ar²) compounds include 65 mol % to about 70 mol % of EtBz. In one embodiment, the disclosed and claimed liquid mixtures of Mo(Ar¹)(Ar²) compounds include 70 mol % to about 75 mol % of EtBz. In one embodiment, the disclosed and claimed liquid mixtures of Mo(Ar¹)(Ar²) compounds include 75 mol % to about 80 mol % of EtBz. In one embodiment, the disclosed and claimed liquid mixtures of Mo(Ar¹)(Ar²) compounds include 80 mol % to about 85 mol % of EtBz. In one embodiment, the disclosed and claimed liquid mixtures of Mo(Ar¹)(Ar²) compounds include 85 mol % to about 90 mol % of EtBz. In one embodiment, the disclosed and claimed liquid mixtures of Mo(Ar¹)(Ar²) compounds include 85 mol % to about 95 mol % of EtBz. In one embodiment, the disclosed and claimed liquid mixtures of Mo(Ar¹)(Ar²) compounds include 90 mol % to about 95 mol % of EtBz.

In one embodiment, the disclosed and claimed liquid mixtures of Mo(Ar¹)(Ar²) compounds include about 60 mol % of EtBz. In one embodiment, the disclosed and claimed liquid mixtures of Mo(Ar¹)(Ar²) compounds include about 65 mol % of EtBz. In one embodiment, the disclosed and claimed liquid mixtures of Mo(Ar¹)(Ar²) compounds include about 70 mol % of EtBz. In one embodiment, the disclosed and claimed liquid mixtures of Mo(Ar¹)(Ar²) compounds include about 75 mol % of EtBz. In one embodiment, the disclosed and claimed liquid mixtures of Mo(Ar¹)(Ar²) compounds include about 80 mol % of EtBz. In one embodiment, the disclosed and claimed liquid mixtures of Mo(Ar¹)(Ar²) compounds include about 85 mol % of EtBz. In one embodiment, the disclosed and claimed liquid mixtures of Mo(Ar¹)(Ar²) compounds include about 90 mol % of EtBz. In one embodiment, the disclosed and claimed liquid mixtures of Mo(Ar¹)(Ar²) compounds include about 91 mol % of EtBz. In one embodiment, the disclosed and claimed liquid mixtures of Mo(Ar¹)(Ar²) compounds include about 92 mol % of EtBz. In one embodiment, the disclosed and claimed liquid mixtures of Mo(Ar¹)(Ar²) compounds include about 93 mol % of EtBz. In one embodiment, the disclosed and claimed liquid mixtures of Mo(Ar¹)(Ar²) compounds include about 94 mol % of EtBz. In one embodiment, the disclosed and claimed liquid mixtures of Mo(Ar¹)(Ar²) compounds include about 95 mol % of EtBz.

### (ii) Undesirable Ligand Content

As noted above the disclosed and claimed liquid mixtures of Mo(Ar¹)(Ar²) compounds include reduced amounts of undesirable ligands, namely (1) benzene ligand (Bz), (2) diethylbenzene ligands (Et₂Bz, three isomers) and (3) triethylbenzene ligands (Et₃Bz, three isomers). As those skilled in the art understand, the total amount of EtBz and any one or more undesirable ligand in a given liquid mixture of Mo(Ar¹)(Ar²) compound does not exceed 100 mol %.

(iia) Benzene Ligand (“Bz”)

In one embodiment, the disclosed and claimed liquid mixtures of Mo(Ar¹)(Ar²) compounds include about 0.25 mol % to about 13 mol % of Bz. In one embodiment, the disclosed and claimed liquid mixtures of Mo(Ar¹)(Ar²) compounds include about 0.5 mol % to about 10 mol % of Bz. In one embodiment, the disclosed and claimed liquid mixtures of Mo(Ar¹)(Ar²) compounds include about 1 mol % to about 10 mol % of Bz. In one embodiment, the disclosed and claimed liquid mixtures of Mo(Ar¹)(Ar²) compounds include about 0.25 mol % to about 5 mol % of Bz. In one embodiment, the disclosed and claimed liquid mixtures of Mo(Ar¹)(Ar²) compounds include about 0.75 mol % to about 5 mol % of Bz. In one embodiment, the disclosed and claimed liquid mixtures of Mo(Ar¹)(Ar²) compounds include about 1 mol % to about 5 mol % of Bz. In one embodiment, the disclosed and claimed liquid mixtures of Mo(Ar¹)(Ar²) compounds include about 2.5 mol % to about 5 mol % of Bz. In one embodiment, the disclosed and claimed liquid mixtures of Mo(Ar¹)(Ar²) compounds include about 5 mol % to about 10 mol % of Bz. In one embodiment, the disclosed and claimed liquid mixtures of Mo(Ar¹)(Ar²) compounds include about 5 mol % to about 13 mol % of Bz. In one embodiment, the disclosed and claimed liquid mixtures of Mo(Ar¹)(Ar²) compounds include about 6 mol % to about 13 mol % of Bz. In one embodiment, the disclosed and claimed liquid mixtures of Mo(Ar¹)(Ar²) compounds include about 7 mol % to about 13 mol % of Bz. In one embodiment, the disclosed and claimed liquid mixtures of Mo(Ar¹)(Ar²) compounds include about 7.5 mol % to about 13 mol % of Bz. In one embodiment, the disclosed and claimed liquid mixtures of Mo(Ar¹)(Ar²) compounds include about 10 mol % to about 13 mol % of Bz.

In one embodiment, the disclosed and claimed liquid mixtures of Mo(Ar¹)(Ar²) compounds include about 0.25 mol % of Bz. In one embodiment, the disclosed and claimed liquid mixtures of Mo(Ar¹)(Ar) compounds include about 0.5 mol % of Bz. In one embodiment, the disclosed and claimed liquid mixtures of Mo(Ar¹)(Ar²) compounds include about 0.75 mol % of Bz. In one embodiment, the disclosed and claimed liquid mixtures of Mo(Ar¹)(Ar²) compounds include about 1 mol % of Bz. In one embodiment, the disclosed and claimed liquid mixtures of Mo(Ar¹)(Ar²) compounds include about 1.5 mol % of Bz. In one embodiment, the disclosed and claimed liquid mixtures of Mo(Ar¹)(Ar²) compounds include about 2.0 mol % of Bz. In one embodiment, the disclosed and claimed liquid mixtures of Mo(Ar¹)(Ar²) compounds include about 2.5 mol % of Bz. In one embodiment, the disclosed and claimed liquid mixtures of Mo(Ar¹)(Ar²) compounds include about 3 mol % of Bz. In one embodiment, the disclosed and claimed liquid mixtures of Mo(Ar¹)(Ar²) compounds include about 3.5 mol % of Bz. In one embodiment, the disclosed and claimed liquid mixtures of Mo(Ar¹)(Ar²) compounds include about 4 mol % of Bz. In one embodiment, the disclosed and claimed liquid mixtures of Mo(Ar¹)(Ar²) compounds include about 4.5 mol % of Bz. In one embodiment, the disclosed and claimed liquid mixtures of Mo(Ar¹)(Ar²) compounds include about 5 mol % of Bz. In one embodiment, the disclosed and claimed liquid mixtures of Mo(Ar¹)(Ar²) compounds include about 5.5 mol % of Bz. In one embodiment, the disclosed and claimed liquid mixtures of Mo(Ar¹)(Ar²) compounds include about 6 mol % of Bz. In one embodiment, the disclosed and claimed liquid mixtures of Mo(Ar¹)(Ar²) compounds include about 6.5 mol % of Bz. In one embodiment, the disclosed and claimed liquid mixtures of Mo(Ar¹)(Ar²) compounds include about 7 mol % of Bz. In one embodiment, the disclosed and claimed liquid mixtures of Mo(Ar¹)(Ar²) compounds include about 7.5 mol % of Bz. In one embodiment, the disclosed and claimed liquid mixtures of Mo(Ar¹)(Ar²) compounds include about 8 mol % of Bz. In one embodiment, the disclosed and claimed liquid mixtures of Mo(Ar¹)(Ar²) compounds include about 8.5 mol % of Bz. In one embodiment, the disclosed and claimed liquid mixtures of Mo(Ar¹)(Ar²) compounds include about 9 mol % of Bz. In one embodiment, the disclosed and claimed liquid mixtures of Mo(Ar¹)(Ar²) compounds include about 9.5 mol % of Bz. In one embodiment, the disclosed and claimed liquid mixtures of Mo(Ar¹)(Ar²) compounds include about 10 mol % of Bz. In one embodiment, the disclosed and claimed liquid mixtures of Mo(Ar¹)(Ar²) compounds include about 10.5 mol % of Bz. In one embodiment, the disclosed and claimed liquid mixtures of Mo(Ar¹)(Ar²) compounds include about 11 mol % of Bz. In one embodiment, the disclosed and claimed liquid mixtures of Mo(Ar¹)(Ar²) compounds include about 11.5 mol % of Bz. In one embodiment, the disclosed and claimed liquid mixtures of Mo(Ar¹)(Ar²) compounds include about 12 mol % of Bz. In one embodiment, the disclosed and claimed liquid mixtures of Mo(Ar¹)(Ar²) compounds include about 12.5 mol % of Bz. In one embodiment, the disclosed and claimed liquid mixtures of Mo(Ar¹)(Ar²) compounds include about 13 mol % of Bz.

(iib) Diethylbenzene Ligand (“Et₂Bz”)

In one embodiment, the disclosed and claimed liquid mixtures of Mo(Ar¹)(Ar²) compounds include about 6.75 mol % to about 44.5 mol % of Et₂Bz. In one embodiment, the disclosed and claimed liquid mixtures of Mo(Ar¹)(Ar²) compounds include about 6.75 mol % to about 10 mol % of Et₂Bz. In one embodiment, the disclosed and claimed liquid mixtures of Mo(Ar¹)(Ar²) compounds include about 10 mol % to about 15 mol % of Et₂Bz. In one embodiment, the disclosed and claimed liquid mixtures of Mo(Ar¹)(Ar²) compounds include about 15 mol % to about 20 mol % of Et₂Bz. In one embodiment, the disclosed and claimed liquid mixtures of Mo(Ar¹)(Ar²) compounds include about 20 mol % to about 25 mol % of Et₂Bz. In one embodiment, the disclosed and claimed liquid mixtures of Mo(Ar¹)(Ar²) compounds include about 25 mol % to about 30 mol % of EtBz. In one embodiment, the disclosed and claimed liquid mixtures of Mo(Ar¹)(Ar²) compounds include about 30 mol % to about 35 mol % of Et₂Bz. In one embodiment, the disclosed and claimed liquid mixtures of Mo(Ar¹)(Ar²) compounds include about 35 mol % to about 40 mol % of Et₂Bz. In one embodiment, the disclosed and claimed liquid mixtures of Mo(Ar¹)(Ar²) compounds include about 40 mol % to about 44.5 mol % of Et₂Bz.

In one embodiment, the disclosed and claimed liquid mixtures of Mo(Ar¹)(Ar²) compounds include about 6.75 mol % of Et₂Bz. In one embodiment, the disclosed and claimed liquid mixtures of Mo(Ar¹)(Ar²) compounds include about 7 mol % of Et₂Bz. In one embodiment, the disclosed and claimed liquid mixtures of Mo(Ar¹)(Ar²) compounds include about 8 mol % of Et₂Bz. In one embodiment, the disclosed and claimed liquid mixtures of Mo(Ar¹)(Ar²) compounds include about 9 mol % of Et₂Bz. In one embodiment, the disclosed and claimed liquid mixtures of Mo(Ar¹)(Ar²) compounds include about 10 mol % of Et₂Bz. In one embodiment, the disclosed and claimed liquid mixtures of Mo(Ar¹)(Ar²) compounds include about 15 mol % of Et₂Bz. In one embodiment, the disclosed and claimed liquid mixtures of Mo(Ar¹)(Ar²) compounds include about 20 mol % of Et₂Bz. In one embodiment, the disclosed and claimed liquid mixtures of Mo(Ar¹)(Ar²) compounds include about 25 mol % of Et₂Bz. In one embodiment, the disclosed and claimed liquid mixtures of Mo(Ar¹)(Ar²) compounds include about 30 mol % of Et₂Bz. In one embodiment, the disclosed and claimed liquid mixtures of Mo(Ar¹)(Ar²) compounds include about 35 mol % of Et₂Bz. In one embodiment, the disclosed and claimed liquid mixtures of Mo(Ar¹)(Ar²) compounds include about 40 mol % of Et₂Bz. In one embodiment, the disclosed and claimed liquid mixtures of Mo(Ar¹)(Ar²) compounds include about 44.5 mol % of Et₂Bz.

(iic) Triethylbenzene Ligand (“Et₃Bz”)

In one embodiment, the disclosed and claimed liquid Mo(Ar¹)(Ar²) compositions include about 0.75 mol % to about 7 mol % of Et₃Bz. In one embodiment, the disclosed and claimed liquid mixtures of Mo(Ar¹)(Ar²) compounds s include about 1 mol % to about 7 mol % of Et₃Bz. In one embodiment, the disclosed and claimed liquid mixtures of Mo(Ar¹)(Ar²) compounds include about 1.5 mol % to about 6.5 mol % of Et₃Bz. In one embodiment, the disclosed and claimed liquid mixtures of Mo(Ar¹)(Ar²) compounds include about 2 mol % to about 6 mol % of Et₃Bz. In one embodiment, the disclosed and claimed liquid mixtures of Mo(Ar¹)(Ar²) compounds include about 3 mol % to about 5 mol % of Et₃Bz. In one embodiment, the disclosed and claimed liquid mixtures of Mo(Ar¹)(Ar²) compounds include about 1 mol % to about 3 mol % of Et₃Bz. In one embodiment, the disclosed and claimed liquid mixtures of Mo(Ar¹)(Ar²) compounds include about 1 mol % to about 5 mol % of Et₃Bz. In one embodiment, the disclosed and claimed liquid mixtures of Mo(Ar¹)(Ar²) compounds include about 1 mol % to about 4 mol % of Et₃Bz. In one embodiment, the disclosed and claimed liquid mixtures of Mo(Ar¹)(Ar²) compounds include about 1 mol % to about 3 mol % of EtBz. In one embodiment, the disclosed and claimed liquid mixtures of Mo(Ar¹)(Ar²) compounds include about 1 mol % to about 2 mol % of Et₃Bz.

In one embodiment, the disclosed and claimed liquid mixtures of Mo(Ar¹)(Ar²) compounds include about 0.75 mol % of Et₃Bz. In one embodiment, the disclosed and claimed liquid mixtures of Mo(Ar¹)(Ar²) compounds include about 1 mol % of Et₃Bz. In one embodiment, the disclosed and claimed liquid mixtures of Mo(Ar¹)(Ar²) compounds include about 1.5 mol % of Et₃Bz. In one embodiment, the disclosed and claimed liquid mixtures of Mo(Ar¹)(Ar²) compounds include about 2 mol % of Et₃Bz. In one embodiment, the disclosed and claimed liquid mixtures of Mo(Ar¹)(Ar²) compounds include about 2.5 mol % of Et₃Bz. In one embodiment, the disclosed and claimed liquid mixtures of Mo(Ar¹)(Ar²) compounds include about 3 mol % of Et₃Bz. In one embodiment, the disclosed and claimed liquid mixtures of Mo(Ar¹)(Ar²) compounds include about 3.5 mol % of Et₃Bz. In one embodiment, the disclosed and claimed liquid mixtures of Mo(Ar¹)(Ar²) compounds include about 4 mol % of Et₃Bz. In one embodiment, the disclosed and claimed liquid mixtures of Mo(Ar¹)(Ar²) compounds include about 4.5 mol % of Et₃Bz. In one embodiment, the disclosed and claimed liquid mixtures of Mo(Ar¹)(Ar²) compounds include about 5 mol % of Et₃Bz. In one embodiment, the disclosed and claimed liquid mixtures of Mo(Ar¹)(Ar²) compounds include about 5.5 mol % of Et₃Bz. In one embodiment, the disclosed and claimed liquid mixtures of Mo(Ar¹)(Ar²) compounds include about 6 mol % of Et₃Bz. In one embodiment, the disclosed and claimed liquid mixtures of Mo(Ar¹)(Ar²) compounds include about 6.5 mol % of EtBz. In one embodiment, the disclosed and claimed liquid mixtures of Mo(Ar¹)(Ar²) compounds include about 7 mol % of Et₃Bz.

### Combinations

In one embodiment, the disclosed and claimed liquid mixtures of Mo(Ar¹)(Ar²) compounds include EtBz and one or more of (1) benzene ligand (Bz), (2) diethylbenzene ligand (Et₂Bz) and (3) triethylbenzene ligand (Et₃Bz) where the total of Ar ligand does not exceed 100 mol %. In this regard, the disclosed and claimed liquid mixtures of Mo(Ar¹)(Ar²) compounds include any combination and amounts thereof of EtBz ligand and one or more of the above-described ligands. For example, in one embodiment, the liquid mixtures of Mo(Ar¹)(Ar²) compounds include (i) about 0.25 mol % to about 13 mol % of Bz ligand, (ii) about 6.75 mol % to about 44.5 mol % of Et₂Bz ligand and (iii) about 0.75 mol % to about 7 mol % of Et₃Bz and where the total amount ligand does not exceed 100 mol %.

II. Specialized Mo(Ar¹)(Ar²) Compositions

In another aspect, the disclosed and claimed subject matter is directed to specialized mixtures of Mo(Ar¹)(Ar²) compounds where (i) Ar¹ and Ar² are different and, (ii) the Ar¹ and Ar² ligands constitute greater than 95 mol % of arene ligands present. In another aspect, the disclosed and claimed subject matter is directed to specialized mixtures of Mo(Ar¹)(Ar²) compounds where (i) Ar¹ and Ar² are different, (ii) the Ar¹ and Ar² ligands constitute greater than about 97 mol % of arene ligands present. In another aspect, the disclosed and claimed subject matter is directed to specialized mixtures of Mo(Ar¹)(Ar²) compounds where (i) Ar¹ and Ar² are different, (ii) the Ar¹ and Ar² ligands constitute about 97 mol % or greater of arene ligands present. In another aspect, the disclosed and claimed subject matter is directed to specialized mixtures of Mo(Ar¹)(Ar²) compounds where (i) Ar¹ and Ar² are different, (ii) the Ar¹ and Ar² ligands constitute about 99 mol % or greater of arene ligands present.

In another aspect, the disclosed and claimed subject matter is directed to specialized mixtures of Mo(Ar¹)(Ar²) compounds where (i) Ar¹ and Ar² are different, (ii) the Ar¹ and Ar² ligands constitute greater than 95 mol % of arene ligands present. In another aspect, the disclosed and claimed subject matter is directed to specialized mixtures of Mo(Ar¹)(Ar²) compounds where (i) Ar¹ and Ar² are different, (ii) the Ar¹ and Ar² ligands constitute greater than about 97 mol % of arene ligands present and (iii) the compounds are liquid. In another aspect, the disclosed and claimed subject matter is directed to specialized mixtures of Mo(Ar¹)(Ar²) compounds where (i) Ar¹ and Ar² are different, (ii) the Ar¹ and Ar² ligands constitute about 97 mol % or greater of arene ligands present. In another aspect, the disclosed and claimed subject matter is directed to specialized mixtures of Mo(Ar¹)(Ar²) compounds where (i) Ar¹ and Ar² are different, (ii) the Ar¹ and Ar² ligands constitute about 99 mol % or greater of arene ligands present.

In one embodiment, the specialized mixture of Mo(Ar¹)(Ar²) compounds has a viscosity of less than or equal to about 500 cP. In one embodiment, the specialized mixture of Mo(Ar¹)(Ar²) compounds has a viscosity of less than or equal to about 250 cP. In one embodiment, the specialized mixture of Mo(Ar¹)(Ar²) compounds has a viscosity of less than or equal to about 100 cP. In one embodiment, the specialized mixture of Mo(Ar¹)(Ar²) compounds has a viscosity of less than or equal to about 50 cP. In one embodiment, the specialized mixture of Mo(Ar¹)(Ar²) compounds has a viscosity of less than or equal to about 25 cP. In one embodiment, the specialized mixture of Mo(Ar¹)(Ar²) compounds has a viscosity of less than or equal to about 15 cP.

### A. Specialized Embodiment 1

In one embodiment, the specialized mixtures include Mo(Ar¹)(Ar²) compounds where (i) Ar¹ and Ar² are each a different arene, (ii) Ar¹ and Ar² each have the same number of carbons. In one embodiment, the specialized mixtures include Mo(Ar¹)(Ar²) compounds where (i) Ar¹ and Ar² are each a different arene, (ii) Ar¹ and Ar² each have the same number of carbons and (iii) the compounds are liquid within a temperature range of about 20° C. to about 35° C.

In one aspect of this embodiment, at least one of Ar¹ and Ar² includes one or more substituent selected from an unsubstituted linear C₁-C₆ alkyl group, a linear C₁-C₆ alkyl group substituted with a halogen, a linear C₁-C₆ alkyl group substituted with an amino group, an unsubstituted branched C₃-C₆ alkyl group, a branched C₃-C₆ alkyl group substituted with a halogen, or a branched C₃-C₆ alkyl group substituted with an amino group, an unsubstituted amine or a substituted amine. In one aspect, at least one of Ar¹ and Ar² includes one or more substituent that is a C₁-C₆ alkyl group. In one aspect, at least one of Ar¹ and Ar² includes one or more substituent that is a linear C₁-C₆ alkyl group substituted with a halogen. In one aspect, at least one of Ar¹ and Ar² includes one or more substituent that is a linear C₁-C₆ alkyl group substituted with an amino group. In one aspect, at least one of Ar¹ and Ar² includes one or more substituent that is an unsubstituted branched C₃-C₆ alkyl group. In one aspect, at least one of Ar¹ and Ar² includes one or more substituent that is a branched C₃-C₆ alkyl group substituted with a halogen. In one aspect, at least one of Ar¹ and Ar² includes one or more substituent that is a branched C₃-C₆ alkyl group substituted with an amino group. In one aspect, at least one of Ar¹ and Ar² includes one or more substituent that is an unsubstituted amine. In one aspect, at least one of Ar¹ and Ar² includes one or more substituent that is a substituted amine. In one preferred aspect, at least one of Ar¹ and Ar² includes one or more substituent that is a C₁-C₃ alkyl group. In one preferred aspect, at least one of Ar¹ and Ar² includes one or more substituent that is a methyl group. In one preferred aspect, at least one of Ar¹ and Ar² includes one or more substituent that is an ethyl group. In one preferred aspect, at least one of Ar¹ and Ar² includes one or more substituent that is a propyl group. In one preferred aspect, at least one of Ar¹ and Ar² includes one substituent. In one preferred aspect, at least one of Ar¹ and Ar² includes two substituents.

In one aspect of this embodiment, each of Ar¹ and Ar² comprises one or more different substituent selected from an unsubstituted linear C₁-C₆ alkyl group, a linear C₁-C₆ alkyl group substituted with a halogen, a linear C₁-C₆ alkyl group substituted with an amino group, an unsubstituted branched C₃-C₆ alkyl group, a branched C₃-C₆ alkyl group substituted with a halogen, or a branched C₃-C₆ alkyl group substituted with an amino group, an unsubstituted amine, or a substituted amine. In one aspect, each of Ar¹ and Ar² includes one or more substituent that is a C₁-C₆ alkyl group. In one aspect, each of Ar¹ and Ar² includes one or more substituent that is a linear C₁-C₆ alkyl group substituted with a halogen. In one aspect, each of Ar¹ and Ar² includes one or more substituent that is a linear C₁-C₆ alkyl group substituted with an amino group. In one aspect, each of Ar¹ and Ar² includes one or more substituent that is an unsubstituted branched C₃-C₆ alkyl group. In one aspect, each of Ar¹ and Ar² includes one or more substituent that is a branched C₃-C₆ alkyl group substituted with a halogen. In one aspect, each of Ar¹ and Ar² includes one or more substituent that is a branched C₃-C₆ alkyl group substituted with an amino group. In one aspect, each of Ar¹ and Ar² includes one or more substituent that is an unsubstituted amine. In one aspect, each of Ar¹ and Ar² includes one or more substituent that is a substituted amine. In one preferred aspect, each of Ar¹ and Ar² includes one or more substituent that is a C₁-C₃ alkyl group. In one preferred aspect, each of Ar¹ and Ar² includes one or more substituent that is a methyl group. In one preferred aspect, each of Ar¹ and Ar² includes one or more substituent that is an ethyl group. In one preferred aspect, each of Ar¹ and Ar² includes one or more substituent that is a propyl group. In one preferred aspect, each of Ar¹ and Ar² includes one substituent. In one preferred aspect, each of Ar¹ and Ar² includes two substituents.

In one aspect, at least one of Ar¹ and Ar² is a 5-member arene. In one aspect, at least one of Ar¹ and Ar² is a 6-member arene. In one aspect, at least one of Ar¹ and Ar² is a 5-member heterocyclic arene. In one aspect, at least one of Ar¹ and Ar² is a 6-member heterocyclic arene. In one aspect, each of Ar¹ and Ar² is a 5-member cyclic arene. In one aspect, each of Ar¹ and Ar² is a 6-member cyclic arene. In one aspect, each of Ar¹ and Ar² is a 5-member heterocyclic arene. In one aspect, each of Ar¹ and Ar² is a 6-member heterocyclic arene. In one aspect, at least one of Ar¹ and Ar² is a substituted benzene, pyridine, pyrrole, furan and thiophene. In one aspect, each of Ar¹ and Ar² is a substituted benzene, pyridine, pyrrole, furan and thiophene.

### B. Specialized Embodiment 2

In another embodiment, the specialized mixtures include Mo(Ar¹)(Ar²) compounds where (i) Ar¹ and Ar² are each a different arene structure. (ii) Ar¹ and Ar² each have substantially the same or the same molecular weight. In another embodiment, the specialized mixtures include Mo(Ar¹)(Ar²) compounds where (i) Ar¹ and Ar² are each a different arene structure, (ii) Ar¹ and Ar² each have substantially the same or the same molecular weight and (iii) the compounds liquid within a temperature range of about 20° C. to about 35° C. As those skilled in the art will understand, in these embodiments neither Ar¹ nor Ar² can be Bz because Bz does not have isomers.

In one aspect of this embodiment, at least one of Ar¹ and Ar² includes one or more substituent selected from an unsubstituted linear C₁-C₆ alkyl group, a linear C₁-C₆ alkyl group substituted with a halogen, a linear C₁-C₆ alkyl group substituted with an amino group, an unsubstituted branched C₃-C₆ alkyl group, a branched C₃-C₆ alkyl group substituted with a halogen, or a branched C₃-C₆ alkyl group substituted with an amino group, an unsubstituted amine, or a substituted amine. In one aspect, at least one of Ar¹ and Ar² includes one or more substituent that is a C₁-C₆ alkyl group. In one aspect, at least one of Ar¹ and Ar² includes one or more substituent that is a linear C₁-C₆ alkyl group substituted with a halogen. In one aspect, at least one of Ar¹ and Ar² includes one or more substituent that is a linear C₁-C₆ alkyl group substituted with an amino group. In one aspect, at least one of Ar¹ and Ar² includes one or more substituent that is an unsubstituted branched C₃-C₆ alkyl group. In one aspect, at least one of Ar¹ and Ar² includes one or more substituent that is a branched C₃-C₆ alkyl group substituted with a halogen. In one aspect, at least one of Ar¹ and Ar² includes one or more substituent that is a branched C₃-C₆ alkyl group substituted with an amino group. In one aspect, at least one of Ar¹ and Ar² includes one or more substituent that is an unsubstituted amine. In one aspect, at least one of Ar¹ and Ar² includes one or more substituent that is a substituted amine. In one preferred aspect, at least one of Ar¹ and Ar² includes one or more substituent that is a C₁-C₃ alkyl group. In one preferred aspect, at least one of Ar¹ and Ar² includes one or more substituent that is a methyl group. In one preferred aspect, at least one of Ar¹ and Ar² includes one or more substituent that is an ethyl group. In one preferred aspect, at least one of Ar¹ and Ar² includes one or more substituent that is a propyl group. In one preferred aspect, at least one of Ar¹ and Ar² includes one substituent. In one preferred aspect, at least one of Ar¹ and Ar² includes two substituents.

In one aspect of this embodiment, each of Ar¹ and Ar² comprises one or more different substituent selected from an unsubstituted linear C₁-C₆ alkyl group, a linear C₁-C₆ alkyl group substituted with a halogen, a linear C₁-C₆ alkyl group substituted with an amino group, an unsubstituted branched C₃-C₆alkyl group, a branched C₃-C₆ alkyl group substituted with a halogen, or a branched C₃-C₆ alkyl group substituted with an amino group, an unsubstituted amine, or a substituted amine. In one aspect, each of Ar¹ and Ar² includes one or more substituent that is a C₁-C₆ alkyl group. In one aspect, each of Ar¹ and Ar² includes one or more substituent that is a linear C₁-C₆ alkyl group substituted with a halogen. In one aspect, each of Ar¹ and Ar² includes one or more substituent that is a linear C₁-C₆ alkyl group substituted with an amino group. In one aspect, each of Ar¹ and Ar² includes one or more substituent that is an unsubstituted branched C₃-C₆ alkyl group. In one aspect, each of Ar¹ and Ar² includes one or more substituent that is a branched C₃-C₆ alkyl group substituted with a halogen. In one aspect, each of Ar¹ and Ar² includes one or more substituent that is a branched C₃-C₆ alkyl group substituted with an amino group. In one aspect, each of Ar¹ and Ar² includes one or more substituent that is an unsubstituted amine. In one aspect, each of Ar¹ and Ar² includes one or more substituent that is a substituted amine. In one preferred aspect, each of Ar¹ and Ar² includes one or more substituent that is a C₁-C₃ alkyl group. In one preferred aspect, each of Ar¹ and Ar² includes one or more substituent that is a methyl group. In one preferred aspect, each of Ar¹ and Ar² includes one or more substituent that is an ethyl group. In one preferred aspect, each of Ar¹ and Ar² includes one or more substituent that is a propyl group. In one preferred aspect, each of Ar¹ and Ar² includes one substituent. In one preferred aspect, each of Ar¹ and Ar² includes two substituents.

In one aspect, at least one of Ar¹ and Ar² is a 5-member arene. In one aspect, at least one of Ar¹ and Ar² is a 6-member arene. In one aspect, at least one of Ar¹ and Ar² is a 5-member heterocyclic arene. In one aspect, at least one of Ar¹ and Ar² is a 6-member heterocyclic arene. In one aspect, each of Ar¹ and Ar² is a 5-member cyclic arene. In one aspect, each of Ar¹ and Ar² is a 6-member cyclic arene. In one aspect, each of Ar¹ and Ar² is a 5-member heterocyclic arene. In one aspect, each of Ar¹ and Ar² is a 6-member heterocyclic arene. In one aspect, at least one of Ar¹ and Ar² is a substituted benzene, pyridine, pyrrole, furan and thiophene. In one aspect, each of Ar¹ and Ar² is a substituted benzene, pyridine, pyrrole, furan and thiophene.

### Representative Specialized Embodiments

In the above embodiments, preferred arene ligands include:

| Arene Ligand | Abbreviation |
|---|---|
| Dimethylbenzene | Me₂Bz |
| ortho-Dimethylbenzene | o-Me₂Bz |
| meta-Dimethylbenzene | m-Me₂Bz |
| para-Dimethylbenzene | p-Me₂Bz |
| Ethylbenzene | EtBz |
| Diethylbenzene | Et₂Bz |
| ortho-Diethylbenzene | o-Et₂Bz |
| meta-Diethylbenzene | m-Et₂Bz |
| para-Diethylbenzene | p-Et₂Bz |
| Triethylbenzene | Et₃Bz |
| Pyridine | Py |
| Ethylpyridine | EtPy |
| 2,6-Lutidine | Lt |

As those skilled in the art will understand, in some embodiments, some arene may include a mixture of isomers. It is to be understood, that unless a specific isomer of a given arene is specified, that a recitation of an arene that can include more than one isomer can include any single or mixtures of such isomers. Thus, for example, when the abbreviation “Me₂Bz” is used it is to be understood to include any one of o-Me₂Bz, m-Me₂Bz and p-Me₂Bz, a mixture of two or more of o-Me₂Bz, m-Me₂Bz and p-Me₂Bz or all three of o-Me₂Bz, m-Me₂Bz and p-Me₂Bz.

In the above embodiments, preferred Mo(Ar¹)(Ar²) compounds include:

Mo(EtBz)(m-Me₂Bz)
Mo(EtBz)(o-Me₂Bz)
Mo(EtBz)(p-Me₂Bz)
Mo(m-Me₂Bz)(o-Me₂Bz)
Mo(m-Me₂Bz)(p-Me₂Bz)
Mo(o-Me₂Bz)(p-Me₂Bz)
Mo(m-Et₂Bz)(o-Et₂Bz)
Mo(m-Et₂Bz)(p-Et₂Bz)

Mo(Ar¹)(Ar²): Ethylbenzene (EtBz) and Dimethylbenzene (“Me₂Bz”) Ligands

A preferred embodiment of the specialized mixtures includes Mo(Ar¹)(Ar²) compounds where (i) one of Ar¹ and Ar² is ethylbenzene (“EtBz”) and the other of Ar¹ and Ar² is dimethylbenzene (“Me₂Bz”). As noted above, in these Mo(Ar¹)(Ar²) compounds, the Ar¹ and Ar² ligands constitute 100 mol % of arene ligands present. Thus, in this embodiment no arene ligands are present in the Mo(Ar¹)(Ar²) compounds other than EtBz and Me₂Bz (i.e., the mol % of EtBz plus the mol % of Me₂Bz equals 100 mol. % of arene ligand present).

In one embodiment, the disclosed and claimed liquid Mo(Ar¹)(Ar²) compounds include up to about 95 mol % of EtBz at least about 5 mol % of Me₂Bz. In one embodiment, the disclosed and claimed liquid Mo(Ar¹)(Ar²) compounds include about 95 mol % to about 60 mol % of EtBz and about 5 mol % to about 40 mol % of Me₂Bz. In one embodiment, the disclosed and claimed liquid Mo(Ar¹)(Ar²) compounds include about 95 mol % to about 90 mol % of EtBz and about 5 mol % to about 10 mol % of Me₂Bz. In one embodiment, the disclosed and claimed liquid Mo(Ar¹)(Ar²) compounds include about 90 mol % to about 85 mol % of EtBz and about 10 mol % to about 15 mol % of Me₂Bz. In one embodiment, the disclosed and claimed liquid Mo(Ar¹)(Ar²) compounds include about 85 mol % to about 80 mol % of EtBz and about 15 mol % to about 20 mol % of Me₂Bz. In one embodiment, the disclosed and claimed liquid Mo(Ar¹)(Ar²) compounds include about 80 mol % to about 75 mol % of EtBz and about 20 mol % to about 25 mol % of Me₂Bz. In one embodiment, the disclosed and claimed liquid Mo(Ar¹)(Ar²) compounds include about 75 mol % to about 70 mol % of EtBz and about 25 mol % to about 30 mol % of Me₂Bz. In one embodiment, the disclosed and claimed liquid Mo(Ar¹)(Ar²) compounds include about 70 mol % to about 65 mol % of EtBz and about 30 mol % to about 35 mol % of Me₂Bz. In one embodiment, the disclosed and claimed liquid Mo(Ar¹)(Ar²) compounds include about 65 mol % to about 60 mol % of EtBz and about 35 mol % to about 40 mol % of Me₂Bz.

### Method of Use

The disclosed and claimed subject matter further includes the use of the mixtures of Mo(Ar¹)(Ar²) compounds to deposit Mo-containing films using any chemical vapor deposition process known to those of skill in the art. As used herein, the term “chemical vapor deposition process” refers to any process wherein a substrate is exposed to one or more volatile precursors, which react and/or decompose on the substrate surface to produce the desired deposition.

In one embodiment, the method includes the use of one or more of the mixtures of Mo(Ar¹)(Ar²) compounds to deposit molybdenum containing films using an atomic layer deposition process (ALD). As used herein, the term “atomic layer deposition process” or ALD refers to a self-limiting (e.g., the amount of film material deposited in each reaction cycle is constant), sequential surface chemistry that deposits films of materials onto substrates of varying compositions. Although the precursors, reagents and sources used herein may be sometimes described as “gaseous,” it is understood that the precursors can be either liquid or solid which are transported with or without an inert gas into the reactor via direct vaporization, bubbling or sublimation. In some case, the vaporized precursors can pass through a plasma generator. The term “reactor” as used herein, includes without limitation, reaction chamber, reaction vessel or deposition chamber.

Chemical vapor deposition processes in which the above mixtures of Mo(Ar¹)(Ar²) compounds can be utilized include, but are not limited to, those used for the manufacture of semiconductor type microelectronic devices such as ALD and plasma enhanced ALD (PEALD). This, in one embodiment, for example, the metal-containing film is deposited using an ALD process. In another embodiment, for example, the metal-containing film is deposited using a plasma enhanced ALD (PEALD) process.

Suitable substrates on which the mixtures of Mo(Ar¹)(Ar²) compounds can be deposited are not particularly limited and vary depending on the final use intended. For example, the substrate may be chosen from oxides such as HfO₂ based materials, TiO₂ based materials, ZrO₂ based materials, rare earth oxide-based materials, ternary oxide-based materials, etc. or from nitride-based films. Other substrates may include solid substrates such as metal substrates (for example, Au. Pd, Rh, Ru. W, Al, Ni, Ti, Co, Pt and metal silicides (e.g., TiSi₂, CoSi₂, and NiSi₂); metal nitride containing substrates (e.g., TaN, TiN, WN, TaCN, TiCN, TaSiN, and TiSiN); semiconductor materials (e.g., Si, SiGe, GaAs, InP, diamond, GaN, and SiC); insulators (e.g., SiO₂, Si₃N₄, SiON, HfO₂, Ta₂O₅, ZrO₂, TiO₂, Al₂O₃, and barium strontium titanate); combinations thereof.

In such deposition methods and processes an oxidizing agent can be utilized. The oxidizing agent is typically introduced in gaseous form. Examples of suitable oxidizing agents include, but are not limited to, oxygen gas, water vapor, ozone, oxygen plasma, or mixtures thereof.

The deposition methods and processes may also involve one or more purge gases. The purge gas, which is used to purge away unconsumed reactants and/or reaction byproducts, is an inert gas that does not react with the precursors. Exemplary purge gases include, but are not limited to, argon (Ar), nitrogen (N₂), helium (He), neon, and mixtures thereof. For example, a purge gas such as Ar is supplied into the reactor at a flow rate ranging from about 10 to about 2000 sccm for about 0.1 to 10000 seconds, thereby purging the unreacted material and any byproduct that may remain in the reactor.

The deposition methods and processes require that energy be applied to the above molybdenum arene precursors to induce reaction and to form the metal-containing film or coating on the substrate. Such energy can be provided by, but not limited to, thermal, plasma, pulsed plasma, helicon plasma, high density plasma, inductively coupled plasma, X-ray, e-beam, photon, remote plasma methods, and combinations thereof. In some processes, a secondary RF frequency source can be used to modify the plasma characteristics at the substrate surface. When utilizing plasma, the plasma-generated process may include a direct plasma-generated process in which plasma is directly generated in the reactor, or alternatively a remote plasma-generated process in which plasma is generated outside of the reactor and supplied into the reactor.

When utilized in such deposition methods and processes the above mixtures of Mo(Ar¹)(Ar²) compounds may be delivered to the reaction chamber such as an ALD reactor in a variety of ways. In some instances, a liquid delivery system may be utilized. In other instances, a combined liquid delivery and flash vaporization process unit may be employed, such as, for example, the turbo vaporizer manufactured by MSP Corporation of Shoreview, MN, to enable low volatility materials to be volumetrically delivered, which leads to reproducible transport and deposition without thermal decomposition of the precursor.

When used in these deposition methods and processes, formulations of the mixtures of Mo(Ar¹)(Ar²) compounds can be mixed with and can include hydrocarbon solvents which are particularly desirable due to their ability to be dried to sub-ppm levels of water. Exemplary hydrocarbon solvents that can be used in the precursors include, but are not limited to, toluene, mesitylene, cumene (isopropylbenzene), p-cymene (4-isopropyl toluene), 1,3-diisopropylbenzene, octane, dodecane, 1,2,4-trimethylcyclohexane, n-butylcyclohexane and decahydronaphthalene (decalin). The disclosed and claimed precursors can also be stored and used in stainless steel containers. In certain embodiments, the hydrocarbon solvent is a high boiling point solvent or has a boiling point of 100 degrees Celsius or greater. The disclosed and claimed precursors can also be mixed with other suitable metal precursors, and the mixture used to deliver both metals simultaneously for the growth of a binary metal-containing films.

A flow of argon and/or other gas may be employed as a carrier gas to help deliver a vapor containing the mixtures of Mo(Ar¹)(Ar²) compounds to the reaction chamber during the precursor pulsing. When delivering the above mixtures of Mo(Ar¹)(Ar²) compounds, the reaction chamber process pressure is between 1 and 50 torr, preferably between 5 and 20 torr.

Substrate temperature can be an important process variable in the deposition of high-quality metal-containing films. Typical substrate temperatures range from about 150° C. to about 550° C. Higher temperatures can promote higher film growth rates.

In view of the forgoing, those skilled in the art will recognize that the disclosed and claimed subject matter further includes the use of the mixtures of Mo(Ar¹)(Ar²) compounds in chemical vapor deposition processes as follows.

In one embodiment, the disclosed and claimed subject matter includes a method for forming a Mo-containing film on at least one surface of a substrate that includes the steps of:
a. providing the at least one surface of the substrate in a reaction vessel;
b. forming a transition metal-containing film on the at least one surface by a thermal chemical vapor deposition (CVD) or atomic layer deposition (ALD) process using one or more of the mixtures of Mo(Ar¹)(Ar²) compounds as a metal source compound for the deposition process.
   In a further aspect of this embodiment, the method includes introducing at least one reactant into the reaction vessel. In a further aspect of this embodiment, the method includes introducing at least one reactant into the reaction vessel where the at least one reactant is selected from the group of water, diatomic oxygen, oxygen plasma, ozone, NO, N₂O, NO₂, carbon monoxide, carbon dioxide and combinations thereof. In another aspect of this embodiment, the method includes introducing at least one reactant into the reaction vessel where the at least one reactant is selected from the group of ammonia, hydrazine, monoalkylhydrazine, dialkylhydrazine, nitrogen, nitrogen/hydrogen, ammonia plasma, nitrogen plasma, nitrogen/hydrogen plasma, and combinations thereof. In another aspect of this embodiment, the method includes introducing at least one reactant into the reaction vessel where the at least one reactant is selected from the group hydrogen, hydrogen plasma, a mixture of hydrogen and helium, a mixture of hydrogen and argon, hydrogen/helium plasma, hydrogen/argon plasma, boron-containing compounds, silicon-containing compounds and combinations thereof.

In one embodiment, the disclosed and claimed subject matter includes a method of forming a Mo-containing film via a cyclic chemical vapor deposition (CCVD) process at temperatures higher than 300° C. that includes the steps of:
a. providing a substrate in a reaction vessel;
b. introducing into the reaction vessel one of the mixtures of Mo(Ar¹)(Ar²) compounds and a source gas;
c. purging the reaction vessel with a second purge gas;
d. sequentially repeating steps b through c until a desired thickness of the transition metal-containing film is obtained.
   In a further aspect of this embodiment, the source gas is one or more of an oxygen-containing source gas selected from water, diatomic oxygen, oxygen plasma, ozone, NO, N₂O, NO₂, carbon monoxide, carbon dioxide and combinations thereof. In another aspect of this embodiment, the source gas is one or more of a nitrogen-containing source gas selected from ammonia, hydrazine, monoalkylhydrazine, dialkylhydrazine, nitrogen, nitrogen/hydrogen, ammonia plasma, nitrogen plasma, nitrogen/hydrogen plasma and mixture thereof. In a further aspect of this embodiment, the method the first and second purge gases are each independently selected one or more of argon, nitrogen, helium, neon, and combinations thereof. In a further aspect of this embodiment, the method further includes applying energy to the one or more precursor, the source gas, the substrate, and combinations thereof, wherein the energy is one or more of thermal, plasma, pulsed plasma, helicon plasma, high density plasma, inductively coupled plasma, X-ray, e-beam, photon, remote plasma methods and combinations thereof. In a further aspect of this embodiment, step b of the method further includes introducing into the reaction vessel the precursor using a stream of carrier gas to deliver a vapor of the precursor into the reaction vessel. In a further aspect of this embodiment, step b of the method further includes use of a solvent medium comprising one or more of toluene, mesitylene, isopropylbenzene, 4-isopropyl toluene, 1,3-diisopropylbenzene, octane, dodecane, 1,2,4-trimethylcyclohexane, n-butylcyclohexane, and decahydronaphthalene and combinations thereof.

In one embodiment, the disclosed and claimed subject matter includes a method of forming a Mo-containing film via a thermal atomic layer deposition (ALD) process or thermal ALD-like process that includes the steps of:
a. providing a substrate in a reaction vessel;
b. introducing into the reaction vessel one of the mixtures of Mo(Ar¹)(Ar²) compounds;
c. purging the reaction vessel with a first purge gas;
d. introducing into the reaction vessel a source gas;
e. purging the reaction vessel with a second purge gas;
f. sequentially repeating steps b through e until a desired thickness of the transition metal-containing film is obtained.
   In a further aspect of this embodiment, the source gas is one or more of an oxygen-containing source gas selected from water, diatomic oxygen, ozone, NO, N₂O, NO₂, carbon monoxide, carbon dioxide and combinations thereof. In another aspect of this embodiment, the source gas is one or more of a nitrogen-containing source gas selected from ammonia, hydrazine, monoalkylhydrazine, dialkylhydrazine, nitrogen, nitrogen/hydrogen, ammonia plasma, nitrogen plasma, nitrogen/hydrogen plasma and mixture thereof. In a further aspect of this embodiment, the method the first and second purge gases are each independently selected one or more of argon, nitrogen, helium, neon, and combinations thereof. In a further aspect of this embodiment, the method further includes applying energy to the one or more precursor, the source gas, the substrate, and combinations thereof, wherein the energy is one or more of thermal, plasma, pulsed plasma, helicon plasma, high density plasma, inductively coupled plasma, X-ray, e-beam, photon, remote plasma methods and combinations thereof. In a further aspect of this embodiment, step b of the method further includes introducing into the reaction vessel the precursor using a stream of carrier gas to deliver a vapor of the precursor into the reaction vessel. In a further aspect of this embodiment, step b of the method further includes use of a solvent medium comprising one or more of toluene, mesitylene, isopropylbenzene, 4-isopropyl toluene, 1,3-diisopropylbenzene, octane, dodecane, 1,2,4-trimethylcyclohexane, n-butylcyclohexane, and decahydronaphthalene and combinations thereof.

### EXAMPLES

Reference will now be made to more specific embodiments of the present disclosure and experimental results that provide support for such embodiments. The examples are given below to more fully illustrate the disclosed and claimed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods:

All reactions and manipulations described in the examples were conducted under a nitrogen atmosphere using an inert atmosphere glove box or standard Schlenk techniques. All chemicals were received from Millipore-Sigma and Strem.

### Comparative Example 1: Synthesis of Mo(EtBz)₂ Compound

5.4 g MoCl₅ was slowly added under nitrogen to a suspension of 0.3 g AlCl₃ and 2.1 g Al in 30 mL anhydrous deoxygenated ethylbenzene under stirring. The mixture was heated to and maintained at 135° C. for 24 h and cooled down to room temperature. Thereafter, 20 mL deoxygenated THF was slowly added to the reaction. The mixture was heated to 100° C. for 8 h. After cooling to room temperature, the volatiles were removed under vacuum. 60 mL pentane was then added, and the mixture was stirred for 1 h. The dark green solution was slowly decanted out to 25 mL deoxygenated KOH solution in a 250 mL flask below 0° C. The organic green solution was washed with 25 mL water after separating from the mixture. The green solution was dried with anhydrous 10 g MgSO₄. The solvent was removed to give 3.7 g dark green liquid. Distillation at 130-170° C./0.075-0.1 mmHg afforded 1.65 g pure product, 30% yield.

### Comparative Example 2: Synthesis of Mo(EtBz)₂ Compound

5.4 g MoCl₅ was slowly added under nitrogen to a suspension of 0.3 g AlCl₃ and 2.1 g Al in 30 mL anhydrous deoxygenated ethylbenzene under stirring. The mixture was heated to and maintained at 135° C. for 24 h and cooled down to room temperature. Thereafter, 20 mL deoxygenated THF was slowly added to the reaction. The mixture was heated to 100° C. for 8 h. After cooling to room temperature, the volatiles were removed under vacuum. 60 mL pentane was then added, and the mixture was stirred for 1 h to form a suspension. The suspension was slowly added to 25 mL deoxygenated KOH solution below 0° C. The organic green solution was washed with 25 mL water after separating from the mixture. The green solution was dried with anhydrous 10 g MgSO₄. The solvent was removed to give 4.0 g dark green liquid. Distillation at 130-170° C./0.075-0.1 mm Hg afforded 2.2 g pure product, 40% yield.

### Example 3: Compositional Analysis of Comparative Mo(EtBz)₂ Compounds

The following analytical method was developed to analyze the Mo(EtBz)₂ compounds. A 50 mg sample was dissolved in 4 mL toluene to form a green solution that was oxidized by oxygen to afford a colorless solution containing arene ligands and a brown solid (MoO species) after filtration. The colorless solution was directly used for GC-FID analysis. The results for commercial product available from Strem and the materials prepared as in Comparative Examples 1 and 2 are summarized in Table 1. GC analysis shows the sample from Comparative Example 1 has a similar composition to the commercial product from Strem. However, the sample from Comparative Example 2 shows the compound contains over 40% Et₂Bz and 6% Et₃Bz when prepared by a different synthetic route. Thus, all these samples contained <60 mol % of EtBz in the mixture of arenes utilized in the Mo(arene)₂ complex.

TABLE 1

| Batch No. | Benzene | Ethylbenzene | Diethylbenzene | Triethylbenzene |
|---|---|---|---|---|
| Commercial Product | 13.11% | 53.94% | 31.08% | 1.86% |
| Example 1 | 11.19% | 53.24% | 34.1% | 1.47% |
| Example 2 | 7.06% | 41.52% | 44.48% | 6.93% |

### Comparative Example 4: Vacuum Evaporation of Commercial Mo(EtBz)₂

A 10.2 g sample from Strem was distilled at different temperatures (135-153° C.) under vacuum. Three fractions (6.5 wt %, 68.6 wt % and 18.6 wt %) were collected and analyzed by GC-FID. GC results were summarized in Table 2. The GC analysis shows three fractions contain different components which may result in inconsistent delivery during vacuum evaporation.

TABLE 2

| | | Amount | | Ethyl- | Diethyl- | Triethyl- |
|---|---|---|---|---|---|---|
| Fraction | Temperature | (Yield) | Benzene | benzene | benzene | benzene |
| 1 | <135° C. | 0.66 g (6.5%) | 16.76% | 54.39% | 27.18% | 1.67% |
| 2 | 135-143° C. | 7.0 g (68.6%) | 10.77% | 51.79% | 34.95% | 2.48% |
| 3 | 143-153° C. | 1.9 g (18.6%) | 6.39% | 46.56% | 43.12% | 3.93% |

### Example 5: Liquid Mo(Ar¹)(Ar²) Compounds (>60 mol % of EtBz)

A mixture of Mo(EtBz)₂ compounds (4.5 g) containing about 7.06% Bz, 41.52% EtBz, 44.48% Et₂Bz and 6.93% Et₃Bz was dissolved in ethylbenzene (22.5 g) to form a green solution. The green solution was heated at 120° C., 125° C., and at 135° C. for 18 h under nitrogen. After cooling the solution to room temperature, a black solid was filtered off and the remaining green filtrate was collected. All volatiles were removed from the green filtrate under vacuum below 90° C. to give a green residue (4.0 g). Distillation at 130-170° C., at 0.1 mm Hg afforded 3.2 g product (80% yield). The product was analyzed by the GC-FID method described in Example 3 and the results were summarized in Table 3.

TABLE 3

| Example | Temperature | Benzene | Ethylbenzene | Diethylbenzene | Triethylbenzene |
|---|---|---|---|---|---|
| 5a | 120° C. | 4.34% | 64.4% | 27.29% | 3.97% |
| 5b | 125° C. | 3.39% | 75.18% | 19.59% | 1.84% |
| 5c | 135° C. | 0.37% | 91.97% | 6.76% | 0.89% |

The GC analysis shows that arene metathesis significantly changed the composition of the Mo(EtBz)₂ mixture. Based on the data in Table 3, EtBz in the mixture increases from 41.5 mol % to above 64% at 120° C., 75 mol % at 125° C., and to 92 mol % at 135° C. The product is still a liquid while other ligands decrease below 0.5 mol % for Bz, below 1 mol % for Et₃Bz, and below 8 mol % for Et₂Bz at 135° C.

### Example 6: Preparation of Mixture of Mo(Ar¹)(Ar²) Compounds with Melting Point <50° C., and >97 mol % of EtBz

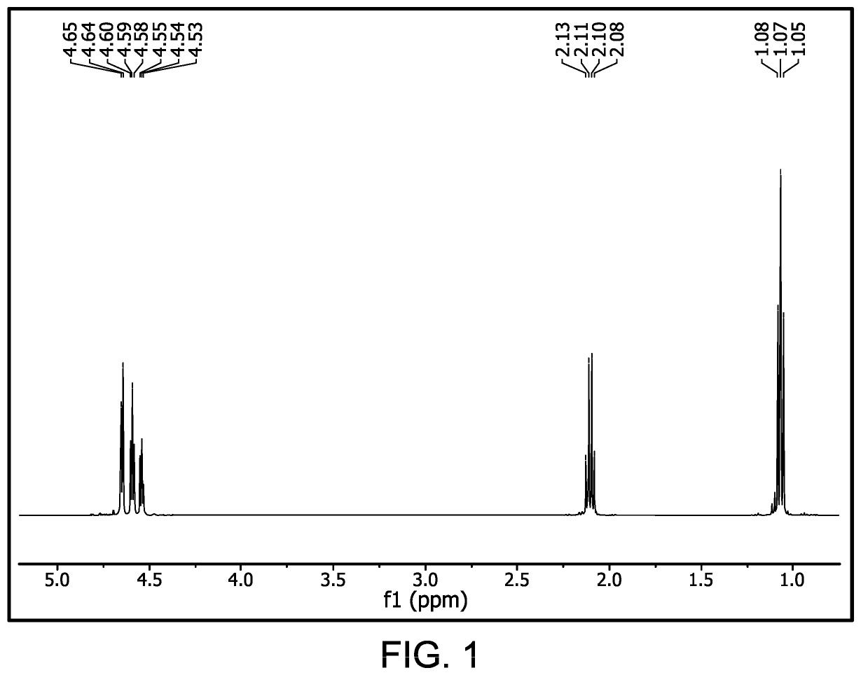

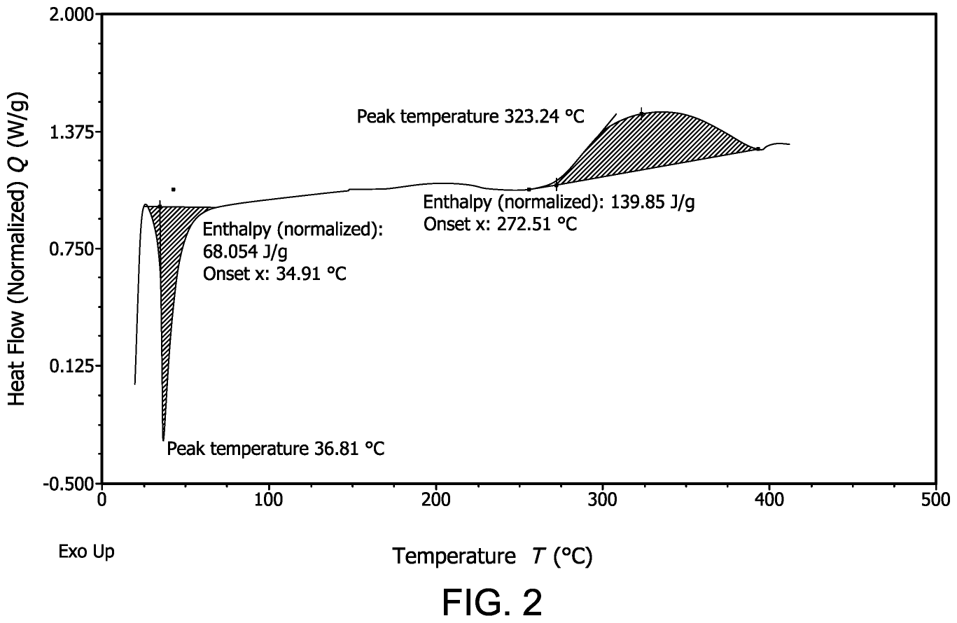

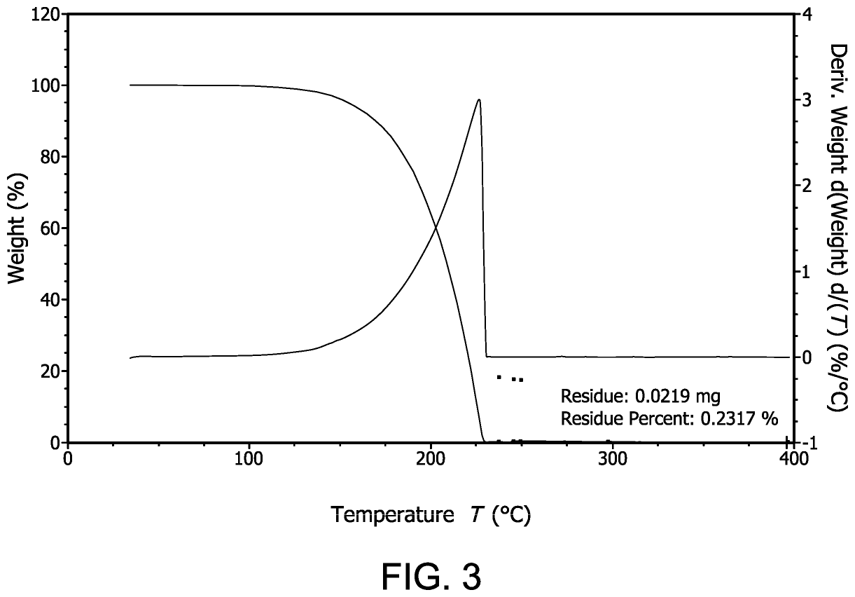

The liquid product from Example 5c was purified by recrystallization to give a green solid. 3.5 g thereof was dissolved in 20 mL of hexane at room temperature. The dark green solution was cooled to −78° C. under dry ice/acetone to give green solid. After filtration, 1.95 g of green solid was isolated (55.7% yield). The ¹H NMR for Mo(EtBz)₂ is shown on FIG. 1: ¹H NMR (C₆D₆, 500 MHz, 20° C.) δ 4.64 (d, 4H, C₆H₅CH₂CH₃), 4.59 (t, 10H, C₆H₅CH₂CH₃), 4.54 (t, 2H, C₆H₅CH₂CH₃), 2.10 (q. 4H, C₆H₅CH₂CH₃), 1.07 (t, 6H, C₆H₅CH₂CH₃); The green solid was also analyzed by DSC and GC-FID as described in Example 3. DSC shows the green solid melts at 36.9° C. (FIG. 2). TGA showed the residue 0.23% (FIG. 3), GC analysis as described in Example 3 shows the sample composition contains 97.17 mol % EtBz, 2.35 mol % Et₂Bz. 0.48 mol % Bz, <0.01 mol % Et₃Bz.

### Example 7: Preparation of Mo Arene Composition Substantially Free of Chlorides

Commercially available molybdenum arenes or molybdenum arenes prepared by literature methods contain at least 27 ppm chloride, as measured by ion chromatography. Residual chloride may cause corrosion in stainless steel container containing molybdenum arenes and/or may cause contamination of molybdenum-containing film deposited from molybdenum arene with undesired chloride. The following procedure was effective to reduce chloride to <5 ppm. A sample of commercially available molybdenum arene (5 g) was dissolved in hexane (100 mL) or MTBE (methyl tert-butyl ether) (100 mL) to form a green solution. The solution was washed twice with 50 mL of 10% KOH/H₂O solution. After separation, the organic solution was dried with anhydrous sodium sulfate. After filtration, the solution was passed through an adsorbent to give a deep green solution. The volatiles were removed under vacuum to give 4.8 g green liquid. The liquid was analyzed by ion chromatography. The results show the chloride is reduced from 27 ppm to less than 1 ppm.

### Example 8: Viscosity of Mo Arene Compositions

Viscosity of commercially available molybdenum arene composition containing a mixture of various arene ligands and described in Example 3 (13.1% of benzene, 54.0% of ethylbenzene, 31.1% of diethylbenzene and 1.9% of triethylbenzene) was measured using capillary viscosimeter tube and a set of ISO 17025 standards available from Paragon Scientific Ltd. The viscosity was 15 cP at 20° C. The viscosity of molybdenum arene composition with larger amount of diethylbenzene and triethylbenzene ligands from Example 2 was 20.5 cP. We have found that improved composition of this invention (sample 5c from Table 3 of Example 5) had substantially lower viscosity of 11 cP at 20° C. The example suggests that reducing the amount of ditehylbenzene and triethylbenzene ligands is critical to reduce viscosity of molybdenum arene composition based on Mo(EtBz)₂. The viscosity <15 cP is important for effective delivery of precursor to deposition tool by direct liquid injection.

### Example 9: Preparation of Mo(m-Me₂Bz)₂ Compound

Under nitrogen, 5.4 g MoCl₅ was slowly added with stirring to a suspension of 2.6 g AlCl₃ and 1.0 g Al in 30 ml, anhydrous deoxygenated m-xylene. The mixture was heated to 135° C. for 20 h and cooled to room temperature. Thereafter, 60 mL MTBE was slowly added to the reaction mixture at room temperature. Next, 100 mL of cold 30% KOH solution was slowly (dropwise first) added to the flask below 0° C. After the KOH addition, the flask was stirred for 4 h. A green organic fraction was then separated from aqueous fraction and washed with water (100 mL). All volatiles are evaporated, and the residue was extracted with hexane/MTBE (100/100 mL) to give a dark green solution that was dried with 10 g Na₂SO₄ inside a glove box. After filtration inside the glove box, all volatiles were removed under vacuum to afford a green solid. The green solid was washed with 10 mL hexane to give 1.95 g of product (32% yield). The solid was analyzed by TGA and DSC. The melting point of this complex was found to be 104° C.

### Example 10: Preparation of Liquid Mixture of Mo(Ar¹)(Ar²) Compounds (where Ar¹ and Ar² are Each Independently Selected Arenes and Mo(EtBz)₂ is Approximately 60%)

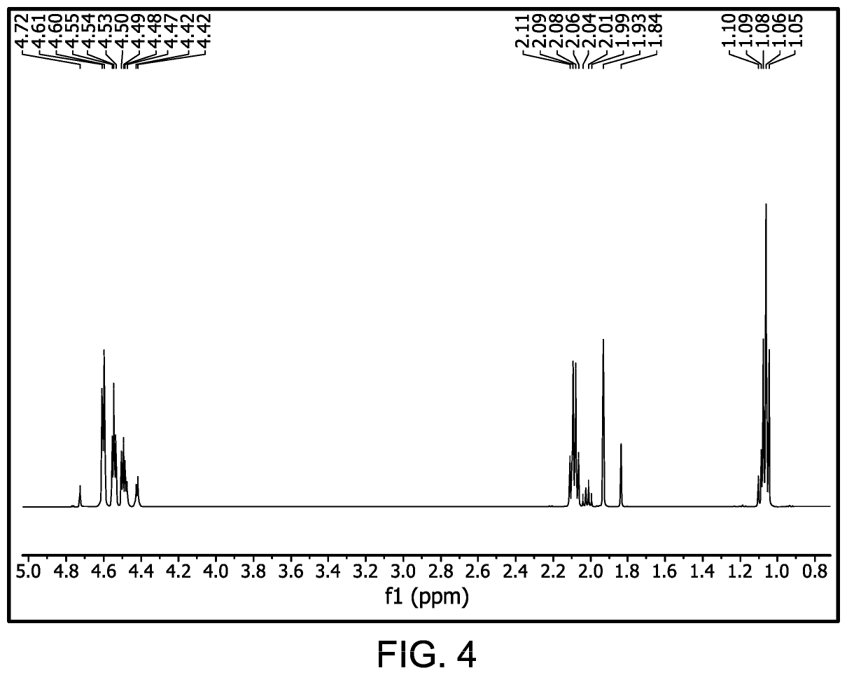

A sample of Mo(m-xylene)₂ (10 g) from Example 9 was dissolved in anhydrous ethylbenzene (80 g) to form a green suspension. The green suspension was heated to 120° C. for 18 h under nitrogen. After cooling the solution to room temperature, a black solid was filtered off via silica gel and the remaining green filtrate was collected. All volatiles were removed from the green filtrate under vacuum below 90° C. to give a green liquid residue. After distillation at 130-150° C., at 0.1 mm Hg, 8.5 g product was obtained with 85% yield. The product was characterized by ¹H NMR spectrum (FIG. 4). The product is a liquid that contains 60% Mo(EtBz)₂, 30% Mo(EtBz)(m-xylene) and 10% Mo(m-xylene)₂ based on NMR analysis. TGA residue was 0.3% and DSC showed an exotherm event at 272° C. Mo(EtBz)₂: ¹H NMR (C₆D₆, 500 MHz, 20° C.) δ 4.60 (d, 4H, C₆H₅CH₂CH₃), 4.54 (t, 10H, C₆H₅CH₂CH₃), 4.50 (m, 2H, C₆H₅CH₂CH₃), 2.09 (q, 4H, C₆H₅SCH₂CH₃), 1.07 (t, 6H, C₆H₅CH₂CH₃); Mo(EtBz)(m-xylene): ¹H NMR (C₆D₆, 500 MHz, 20° C.) δ 4.72 (s, 1H, C₆H₅(CH₃)₂), 4.54 (m, 1H, C₆H₅(CH₃)₂), 4.42 (m, 2H, C₆H₅(CH₃)₂), 2.01 (q, 2H, C₆H₅CH₂CH₃), 1.93 (s, 6H, C₆H₅(CH₂)₂), 1.09 (t, 3H, C₆H₅CH₂CH₃); Mo(m-xylene)₂: ¹H NMR (C₆D₆, 500 MHz, 20° C.) δ 4.54 (s, 2H, C₆H₅(CH₃)₂), 4.50 (m, 6H, C₆H₅(CH₃)₂), 1.84 (s, 12H, C₆H₅(CH₂)₂).

### Example 11: Preparation of Liquid Mixture of Mo(Ar¹)(Ar²) Compounds (where Ar¹ and Ar² are Each Independently Selected Arenes and Mo(EtBz)₂ is Approximately 80%)

A sample of Mo(m-xylene)₂ (27 g) from Example 9 was dissolved in anhydrous ethylbenzene (135 g) to form a green suspension. The green suspension was heated to 120° C. for 24 h under nitrogen. After cooling the solution to room temperature, a black solid was filtered off via silica gel and the remaining green filtrate was collected. All volatiles were removed from the green filtrate under vacuum to give a green liquid residue. After distillation at 130-142° C., at 0.1 mm Hg, 25 g product was obtained with 92% yield. The product was characterized by NMR spectrum and the composition was analyzed based on the peak integration described in Example 10. The product contains 80.5% Mo(EtBz)₂, 18% Mo(EtBz)(m-xylene) and 1.5% Mo(m-xylene)₂ based on NMR analysis. TGA residue was 0.013% and DSC showed an exotherm event at 278° C.

### Example 12: Preparation of Liquid Mixture of Mo(Ar¹)(Ar²) Compounds (where Ar¹ and Ar² are Each Independently Selected Arenes and Mo(EtBz)₂ is Approximately 80%)

A sample of Mo(m-xylene)₂ (69 g) from Example 9 was dissolved in anhydrous ethylbenzene (420 g) to form a green suspension. The green suspension was heated to 130° C. for 24 h under nitrogen. After cooling the solution to room temperature, a black solid was filtered off via silica gel and the remaining green filtrate was collected. All volatiles were removed from the green filtrate under vacuum to give a green liquid residue. After distillation at 130-140° C., at 0.15-0.2 mm Hg, 61.5 g product was obtained with 89% yield. The product was characterized by NMR spectrum and the composition was analyzed based on the peak integration described in Example 10. The product contains 80% Mo(EtBz)₂, 18% Mo(EtBz)(m-xylene) and 2% Mo(m-xylene)₂ based on NMR analysis. TGA residue was 0.05% and DSC showed an exotherm event at 280° C.

### Example 13: Preparation of Liquid Mixture of Mo(Ar¹)(Ar²) Compounds (where Ar¹ and Ar² are Each Independently Selected Arenes and Mo(m-Xylene)₂ is Above 15%)

A sample of Mo(m-xylene)₂ (52 g) from Example 9 was dissolved in anhydrous ethylbenzene (290 g) to form a green suspension. The green suspension was heated to 132° C. for 24 h under nitrogen. After cooling the solution to room temperature, a black solid was filtered off via silica gel and the remaining green filtrate was collected. All volatiles were removed from the green filtrate under vacuum to give a green liquid residue. After distillation at 130-140° C., at 0.15-0.2 mm Hg. 47 g product was obtained with 90% yield. The product was characterized by NMR spectrum and the composition was analyzed based on the peak integration described in Example 10 and the results were summarized in Table 4. The product contains 65% Mo(EtBz)₂, 19% Mo(EtBz)(m-xylene) and 16% Mo(m-xylene)₂ based on NMR analysis. After overnight, solid was formed inside flask. TGA residue was 1% and DSC showed an exotherm event at 272° C. The experiment shows that to avoid the formation of solids in desired liquid formulation the amount of residual Mo(m-xylene)₂ should be <15 mol %.

### Example 14: Viscosity of Liquid Mixture of Mo(Ar¹)(Ar²) Compounds (where Ar¹ and Ar² are Each Independently Selected Arenes and Mo(EtBz)₂ is Approximately 80%)

A sample of Mo(m-xylene)₂ (55 g) from Example 9 was dissolved in anhydrous ethylbenzene (250 g) to form a green suspension. The green suspension was heated to 139.7° C. for 24 h under nitrogen. After cooling the solution to room temperature, a black solid was filtered off via silica gel and the remaining green filtrate was collected. Mirror Mo metal was found on the top of silica gel after filtration through silica gel. All volatiles were removed from the green filtrate under vacuum to give a green liquid residue. 50 g product was obtained with 90% yield. The product was characterized by NMR spectrum and the composition was analyzed based on the peak integration described in Example 10 and the results were summarized in Table 4. The product contains 81% Mo(EtBz)₂, 17.4% Mo(EtBz)(m-xylene) and 1.6% Mo(m-xylene)₂ based on NMR analysis. The viscosity of this sample was 10 mPa-s, substantially lower than commercially available composition containing Mo(EtBz)₂. Trace metal analysis by ICP-MS shows that this composition only contains less than 3 ppm of aluminum. Ion chromatography showed that the amount of residual chloride was also reduced to <1 ppm.

The composition of molybdenum arene mixtures from examples 10-14 is summarized in Table 4:

TABLE 4

| Example | Mo(EtBz)₂ | Mo(EtBz)(m-xylene) | Mo(m-xylene)₂ | EtBz:m-xylene |
|---|---|---|---|---|
| 10 | 60 | 30 | 10 | 75:25 |
| 11 | 80.5 | 18 | 1.5 | 89.5:10.5 |
| 12 | 80 | 18 | 2 | 89:11 |
| 13 | 65 | 19 | 16 | 74.5:25.5 |
| 14 | 81 | 17.4 | 1.6 | 89.7:10.3 |

### Example 15: Preparation of Liquid Mixture of Mo(Ar¹)(Ar²) Compounds (where Ar¹ and Ar² are Each Independently Selected Arenes and Mo(EtBz)₂ is Above 90%)

110 g of the composition from Example 12 was dissolved in anhydrous ethylbenzene (120 g) to form a green suspension. The suspension was heated to 137° C. for 24 h under nitrogen. After cooling the solution to room temperature, a black solid was filtered off via silica gel and the remaining green filtrate was collected. All volatiles were removed from the green filtrate under vacuum to give a green liquid residue. The product was characterized by NMR spectrum and the composition was analyzed based on the peak integration described in Example 10. The product contains 90% Mo(EtBz)₂, 9.5% Mo(EtBz)(m-xylene) and 0.5% Mo(m-xylene)₂ based on NMR analysis.

### Example 16: Deposition of Mo-Containing Film Using Thermal Hydrogen And Liquid Mixture of Mo(Ar¹)(Ar²) Compounds (where Ar¹ and Ar² are Each Independently Selected Arenes and Mo(EtBz)₂ is Approximately 70%)

In the deposition process, molybdenum arene compound containing 70.6% of Mo(EtBz)₂, 22.0% of Mo(EtBz)(m-xylene) and 7.4% of Mo(m-xylene)₂ was delivered to deposition reactor chamber by passing 50 sccm argon through stainless steel container filled with the compound and heated to 110° C. Chamber pressure was 20 torr. The substrates were TiN, Cu, Pt and SiO₂. Mo-containing films were deposited via a cyclic chemical vapor deposition (CCVD) process at 400° C. that includes the steps of:
a. providing a substrate in a deposition reactor chamber;
b. introducing into the deposition reactor chamber molybdenum arene vapor for 10 seconds;
c. purging the deposition reactor chamber with argon purge gas for 30 sec;
d. introducing into the deposition reactor chamber hydrogen gas for 10 sec at 1000 sccm;
e. purging the deposition reactor chamber with argon purge for 10 sec; and
f. sequentially repeating steps b through e 100 times
   Film thickness of molybdenum-containing films on different substrates is summarized in Table 5.

| Substrate | Film Thickness (Å) |
|---|---|
| SiO₂ | 0.0 |
| TiN | 5.3 |
| Cu | 29.1 |
| Pt | 3.8 |

The example shows selective deposition of Mo-containing film on Cu substrate

### Example 17: Deposition of Mo-Containing Film Using Diiodobutane and Liquid Mixture of Mo(Ar¹)(Ar²) Compounds (where Ar¹ and Ar² are Each Independently Selected Arenes and Mo(EtBz)₂ is Approximately 70%)

In the deposition process, molybdenum arene compound containing 70.6% of Mo(EtBz)₂, 22.0% of Mo(EtBz)(m-xylene) and 7.4% of Mo(m-xylene)₂ delivered to deposition reactor chamber by passing 50 sccm argon through stainless steel container filled with the compound and heated to 110° C. Chamber pressure was 10 torr. The substrates were TiN, Cu, Pt and SiO₂. Separate pulses of diiodobutane were also delivered to the deposition reactor chamber by passing 50 sccm argon through stainless steel container filled with the diidobutane and heated to 50° C. Mo-containing films were deposited via a cyclic chemical vapor deposition (CCVD) process at 400° C. that includes the steps of:
a. providing a substrate in a deposition reactor chamber;
b. introducing into the deposition reactor chamber molybdenum arene vapor for 20 seconds;
c. purging the deposition reactor chamber with argon purge gas for 30 seconds;
d. introducing into the deposition reactor chamber diiodobutane vapor for 20 seconds;
e. purging the deposition reactor chamber with argon purge for 42 seconds; and
f. sequentially repeating steps b through e 100 times.
   Film thickness of molybdenum-containing films on different substrates is summarized in Table 6

| Substrate | Film Thickness (Å) |
|---|---|
| SiO₂ | 187 |
| TiN | 187 |
| Cu | 299 |
| Pt | 195 |

Resistivity of Mo-containing film deposited on silicon oxide was measured by four-point probe method and was 260 μOhm cm.

### Example 18: Deposition of Mo-Containing Film Using Diiodobutane and Liquid Mixture of Mo(Ar¹)(Ar²) Compounds (where Ar¹ and Ar² are Each Independently Selected Arenes and Mo(EtBz)₂ is Approximately 70%)

In the deposition process, molybdenum arene compound containing 70.6% of Mo(EtBz)₂, 22.0% of Mo(EtBz)(m-xylene) and 7.4% of Mo(m-xylene)₂ delivered to deposition reactor chamber by passing 50 sccm argon through stainless steel container filled with the compound and heated to 110° C. Chamber pressure was 10 torr. The substrates were TiN, Cu, Pt and SiO₂. Separate pulses of diiodobutane were also delivered to the deposition reactor chamber by passing 50 sccm argon through stainless steel container filled with the diidobutane and heated to 50° C. Mo-containing films were deposited via a cyclic chemical vapor deposition (CCVD) process at 300° C. that includes the steps of:
a. providing a substrate in a deposition reactor chamber;
b. introducing into the deposition reactor chamber molybdenum arene vapor for 20 seconds
c. purging the deposition reactor chamber with argon purge gas for 30 seconds;
d. introducing into the deposition reactor chamber diiodobutane vapor for 2 seconds;
e. purging the deposition reactor chamber with argon purge for 42 sec
f. sequentially repeating steps b through e 100 times
   Film thickness of molybdenum-containing films on different substrates is summarized in Table 7

| Substrate | Film Thickness (Å) |
|---|---|
| SiO₂ | 237 |
| TiN | 273 |
| Cu | 636 |
| Pt | 299 |

Resistivity of Mo-containing film deposited on silicon oxide was measured by four-point probe method and was 131 μOhm cm. The example shows deposition of Mo-containing film with resistivity below 150 μOhm cm. It is anticipated that film resistivity could be reduced below 50 μOhm with further process optimization.

It is anticipated that the inventive method could be used in conjunction with deposition tools commonly found at semiconductor manufacturing sites to produce molybdenum-containing layers for logic applications and other potential functions.

The foregoing description is intended primarily for purposes of illustration. Although the disclosed and claimed subject matter has been shown and described with respect to an exemplary embodiment thereof, it should be understood by those skilled in the art that the foregoing and various other changes, omissions, and additions in the form and detail thereof may be made therein without departing from the spirit and scope of the disclosed and claimed subject matter.

1. A mixture of Mo(Ar¹)(Ar²) compounds comprising about 60 mol % to about 95 mol % of EtBz ligand, wherein Ar¹ and Ar² are arene ligands and the mol % is based on the total moles of Ar¹ and Ar², wherein the compounds are liquid.

2-11. (canceled)

12. The mixture of Mo(Ar¹)(Ar²) compounds of claim 1, wherein the mixture further comprises about 0.25 mol % to about 13 mol % of Bz ligand and wherein a total amount ligand does not exceed 100 mol %.

13-15. (canceled)

16. The mixture of Mo(Ar¹)(Ar²) compounds of claim 1, wherein the mixture further comprises about 6.75 mol % to about 44.5 mol % of Et₂Bz ligand and wherein a total amount ligand does not exceed 100 mol %.

17-19. (canceled)

20. The mixture of Mo(Ar¹)(Ar²) compounds of claim 1, wherein the mixture further comprises about 0.75 mol % to about 7 mol % of Et₃Bz ligand and wherein a total amount ligand does not exceed 100 mol %.

21-23. (canceled)

24. The mixture of Mo(Ar¹)(Ar²) compounds of claim 1, wherein the mixture further comprises (i) about 0.25 mol % to about 13 mol % of Bz ligand, (ii) about 6.75 mol % to about 44.5 mol % of Et₂Bz ligand and (iii) about 0.75 mol % to about 7 mol % of Et₃Bz and wherein a total amount ligand does not exceed 100 mol %.

25-28. (canceled)

29. The mixture of Mo(Ar¹)(Ar²) compounds of claim 1, wherein the mixture of Mo(Ar¹)(Ar²) compounds has a viscosity of less than or equal to about 25 cP.

30. The mixture of Mo(Ar¹)(Ar²) compounds of claim 1, wherein the mixture of Mo(Ar¹)(Ar²) compounds has a viscosity of less than or equal to about 15 cP.

31. A mixture comprising Mo(Ar¹)(Ar²) compounds wherein
(i) Ar¹ and Ar² each comprises a different arene structure; and
(ii) Ar¹ and Ar² each have a same number of carbons and/or substantially the same molecular weight.

32. The mixture of claim 31, wherein the compounds are liquid within a temperature range of about 20° C. to about 35° C.

33. The mixture of claim 31, wherein at least one of Ar¹ and Ar² comprises one or more substituent selected from an unsubstituted linear C₁-C₆ alkyl group, a linear C₁-C₆ alkyl group substituted with a halogen, a linear C₁-C₆ alkyl group substituted with an amino group, an unsubstituted branched C₃-C₆ alkyl group, a branched C₃-C₆ alkyl group substituted with a halogen, or a branched C₃-C₆ alkyl group substituted with an amino group, an unsubstituted amine, or a substituted amine.

34. (canceled)

35. The mixture of claim 31, wherein at least one of Ar¹ and Ar² comprises one or more substituent that is an unsubstituted linear C₁-C₃ alkyl group.

36. (canceled)

37. (canceled)

38. The mixture of claim 31, wherein at least one of Ar¹ and Ar² comprises one or more methyl group.

39. The mixture of claim 31, wherein at least one of Ar¹ and Ar² comprises one or more ethyl group.

40. The mixture of claim 31, wherein at least one of Ar¹ and Ar² comprises one or more propyl group.

41-51. (canceled)

52. The mixture of claim 31, wherein one of Ar¹ and Ar² is EtBz and the other of Ar¹ and Ar² is Me₂Bz.

53. The mixture of claim 31, wherein one of Ar¹ and Ar² is EtBz and the other of Ar¹ and Ar² is meta-Me₂Bz.

54-57. (canceled)

58. The mixture of claim 31, wherein the mixture comprising Mo(Ar¹)(Ar²) compounds has a viscosity of less than or equal to about 25 cP.

59. The mixture of claim 31, wherein the mixture comprising Mo(Ar¹)(Ar²) compounds has a viscosity of less than or equal to about 15 cP.

60. The mixture of claim 31, wherein Ar¹ and Ar² have the same number of carbons.

61. The mixture of claim 31, wherein Ar¹ and Ar² have substantially the same molecular weight.

62. The mixture of claim 31, wherein Ar¹ and Ar² have the same molecular weight.

63-90. (canceled)

91. The mixture of Mo(Ar¹)(Ar²) compounds of claim 1, wherein the mixture is substantially free of chloride ions.

92. (canceled)

93. The mixture of claim 31, wherein the mixture is substantially free of chloride ions.

94. (canceled)

95. (canceled)

96. A method for forming a transition metal-containing film on at least one surface of a substrate comprising:
a. providing the at least one surface of the substrate in a reaction vessel;
b. forming a transition metal-containing film on the at least one surface by chemical vapor deposition (CVD) or an atomic layer deposition (ALD) process using one or more of the mixtures of claim 31.

97-108. (canceled)
